(19) United States
(12) Patent Application Publication
(10) Pub. No.: US 2024/0040869 A1
(43) Pub. Date: Feb. 1, 2024

(54) DISPLAY PANEL

(71) Applicant: SAMSUNG DISPLAY CO., LTD., Yongin-si (KR)

(72) Inventors: Seunghwan CHO, Yongin-si (KR); Kyungmin KIM, Yongin-si (KR); Sangwoo KIM, Yongin-si (KR); Taehyun KIM, Yongin-si (KR); Jongho HONG, Yongin-si (KR)

(21) Appl. No.: 18/226,396

(22) Filed: Jul. 26, 2023

(30) Foreign Application Priority Data
Jul. 27, 2022 (KR) 10-2022-0093464

(51) Int. Cl. H10K 59/131; H10K 59/121; H10K 59/80

(52) U.S. Cl. CPC H10K 59/131; H10K 59/1213; H10K 59/873

(57) ABSTRACT

A display panel includes a substrate including a central area and a corner area extending from a corner of the central area, a pixel circuit disposed in the central area and a display element connected to the pixel circuit, a voltage supply line which is disposed in the corner area and supplies a voltage to one electrode of the display element, and a driving circuit which is disposed in the corner area and supplies an electrical signal to the pixel circuit. The driving circuit is spaced apart from the central area with the voltage supply line therebetween.

This application claims priority to Korean Patent Application No. 10-2022-0093464, filed on Jul. 27, 2022, and all the benefits accruing therefrom under 35 U.S.C. § 119, the content of which in its entirety is herein incorporated by reference.

### BACKGROUND

### 1. Field

Embodiments relate to a display panel and a display apparatus. More particularly, embodiments relate to a display panel and a display apparatus in which an edge is curved.

### 2. Description of the Related Art

Recently, a design of display apparatuses is being diversified. A curved display apparatus, a foldable display apparatus, and a rollable display apparatus, for example, are being developed. Also, a display area is being increased, and a non-display area is being decreased. Accordingly, various methods are being derived to design shapes of display apparatuses.

### SUMMARY

Embodiments include a display panel and a display apparatus in which a display area for displaying an image is increased and reliability is improved.

Embodiments include a display panel and a display apparatus in which a corner area that is disposed to correspond to a corner of the display panel and is bendable is included and reliability is improved.

Additional features will be set forth in part in the description which follows and, in part, will be apparent from the description, or may be learned by practice of the presented embodiments.

In an embodiment of the disclosure, a display panel includes a substrate including a central area and a corner area extending from a corner of the central area, a pixel circuit disposed in the central area and a display element connected to the pixel circuit, a voltage supply line which is disposed in the corner area and supplies a voltage to one electrode of the display element, and a driving circuit which is disposed in the corner area and supplies an electrical signal to the pixel circuit. The driving circuit is spaced apart from the central area with the voltage supply line therebetween.

In an embodiment, the corner area may include a first corner area adjacent to the central area and a second corner area outside the first corner area. The voltage supply line may be disposed in the first corner area, and the driving circuit may be disposed in the second corner area.

In an embodiment, the display panel may further include a thin-film encapsulation layer disposed on the display element. The thin-film encapsulation layer may include a first inorganic encapsulation layer, an organic encapsulation layer on the first inorganic encapsulation layer, and a second inorganic encapsulation layer on the organic encapsulation layer.

In an embodiment, the first inorganic encapsulation layer and the second inorganic encapsulation layer may contact each other in the first corner area and the second corner area.

In an embodiment, the organic encapsulation layer may overlap at least a part of the voltage supply line and does not overlap the driving circuit.

In an embodiment, in a cross-sectional view, the first inorganic encapsulation layer and the second inorganic encapsulation layer may be spaced apart from each other in a portion of the first corner area.

In an embodiment, the display panel may further include a dam provided over the voltage supply line to at least partially overlap the voltage supply line, the dam being disposed between the pixel circuit and the driving circuit.

In an embodiment, the second corner area may include a plurality of extending areas, and the driving circuit may include a plurality of sub-driving circuits. At least one of the plurality of sub-driving circuits may be disposed in each of the plurality of extending areas.

In an embodiment, the display panel may further include an organic insulating layer disposed on the substrate and covering the pixel circuit, and an inorganic insulating layer disposed between the substrate and the organic insulating layer. A first opening between the pixel circuit and the voltage supply line in the first corner area and a second opening corresponding to the voltage supply line may be defined in the organic insulating layer.

In an embodiment, the organic insulating layer may be disposed over the driving circuit in the second corner area, and a third opening between the driving circuit and the voltage supply line may be further defined in the organic insulating layer. The first inorganic encapsulation layer and the second inorganic encapsulation layer may be disposed in the third opening.

In an embodiment, the display panel may further include at least one conductive layer disposed in the second opening of the organic insulating layer, and contacting the voltage supply line, and an electrode disposed on an uppermost layer of the at least one conductive layer. The electrode may be an extending portion of the one electrode of the display element.

In an embodiment, the display panel may further include a first input line disposed in the first corner area, a second input line disposed in the second corner area and connected to the driving circuit, and a third input line connecting the first input line to the second input line.

In an embodiment, each of the first input line, the second input line, and the third input line may be spaced apart from the central area with the voltage supply line therebetween.

In an embodiment, the first input line may be disposed in a same layer as the second input line and may be disposed in a different layer from the third input line.

In an embodiment, the first input line may overlap the voltage supply line in a direction perpendicular to a top surface of the substrate.

In an embodiment, the display panel may further include a crack-preventing dam disposed at an end of the corner area.

In an embodiment of the disclosure, a display panel includes a substrate including a central area and a corner area extending from a corner of the central area. The corner area includes a first corner area adjacent to the central area and a second corner area outside the first corner area, a pixel circuit disposed in the central area and a display element connected to the pixel circuit, a voltage supply line which is disposed in the first corner area and supplies a voltage to one electrode of the pixel circuit, a driving circuit which is disposed in the second corner area and supplies an electrical signal to the pixel circuit, and an input line which is disposed outside the voltage supply line in the corner area and transmits a signal to the driving circuit.

In an embodiment, the display panel may further include a thin-film encapsulation layer including a first inorganic encapsulation layer disposed on the display element, an organic encapsulation layer on the first inorganic encapsulation layer, and a second inorganic encapsulation layer on the organic encapsulation layer. The organic encapsulation layer may be disposed in the central area and the corner area, and does not overlap the driving circuit.

In an embodiment, the input line may include a first input line disposed in the first corner area, a second input line disposed in the second corner area and connected to the driving circuit, and a third input line connecting the first input line to the second input line. The third input line may include a 3-1^{st} input line disposed in a layer at a lower level than the first input line, and a 3-2^{nd} input line disposed in a layer at a higher level than the first input line.

In an embodiment, the second corner area may include a plurality of extending areas, and the driving circuit may include a plurality of sub-driving circuits. At least one of the plurality of sub-driving circuits may be disposed in each of the plurality of extending areas.

### BRIEF DESCRIPTION OF THE DRAWINGS

The above and other features and advantages of certain embodiments will be more apparent from the following description taken in conjunction with the accompanying drawings, in which:

FIG. 1 is a perspective view schematically illustrating an embodiment of a part of a display apparatus,

FIGS. 2A, 2B, and 2C are each a cross-sectional view schematically illustrating an embodiment of a display apparatus;

FIG. 3 is a plan view schematically illustrating an embodiment of a part of a display apparatus;

FIGS. 4A and 5A are each an equivalent circuit diagram schematically illustrating a pixel circuit applicable to a display panel;

FIGS. 4B and 5B are each a configuration diagram schematically illustrating an embodiment of a display panel;

FIG. 6 is an enlarged view illustrating an embodiment of a part of a display apparatus;

FIGS. 7A and 7B are each a diagram schematically illustrating an embodiment of a driving circuit;

FIG. 8A is a cross-sectional view schematically illustrating an embodiment of a display panel, taken along line IV-IV′ of FIG. 6;

FIG. 8B is a cross-sectional view schematically illustrating an embodiment of a display panel, taken along line V-V′ of FIG. 6;

FIG. 9 is a cross-sectional view schematically illustrating another embodiment of a display panel, taken along line IV-IV′ of FIG. 6;

FIG. 10 is a cross-sectional view schematically illustrating another embodiment of a display panel, taken along line IV-IV′ of FIG. 6;

FIG. 11 is a plan view schematically illustrating another embodiment of a part of a display apparatus;

FIG. 12 is a cross-sectional view schematically illustrating an embodiment of a display panel, taken along line VI-VI′ of FIG. 11;

FIG. 13 is an enlarged view schematically illustrating an embodiment of a portion F of FIG. 6; and

FIG. 14 is an enlarged view schematically illustrating another embodiment of the portion F of FIG. 6.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Reference will now be made in detail to embodiments, examples of which are illustrated in the accompanying drawings, and in the drawings, the same elements are denoted by the same reference numerals, and thus a repeated description thereof will be omitted.

Although the terms “first,” “second,” etc., may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be further understood that the terms “comprises” or “comprising” used herein specify the presence of stated features or components, but do not preclude the presence or addition of one or more other features or components.

It will be further understood that, when a layer, region, or component is also referred to as being “on” another layer, region, or component, it may be directly on the other layer, region, or component, or may be indirectly on the other layer, region, or component with intervening layers, regions, or components therebetween.

Sizes of components in the drawings may be exaggerated or contracted for convenience of explanation. For example, because sizes and thicknesses of elements in the drawings are arbitrarily illustrated for convenience of explanation, the disclosure is not limited thereto.

It will be understood that when a layer, region, or component is referred to as being “connected,” the layer, the region, or the component may be directly connected or may be indirectly connected with intervening layers, regions, or components therebetween. For example, when layers, regions, or components are referred to as being “electrically connected,” the layers, the regions, or the components may be directly electrically connected, or may be indirectly electrically connected with intervening layers, regions, or components therebetween.

“A and/or B” is used herein to select only A, select only B, or select both A and B. Also, “at least one of A and B” is used herein to select only A, select only B, or select both A and B.

In the following embodiments, “a plan view of an object” refers to “a view of an object seen from above, and “a cross-sectional view of an object” refers to “a view of an object vertically cut and seen from the side. In the following embodiments, when a first element “overlaps” a second element, it means that the first element is disposed over or under the second element.

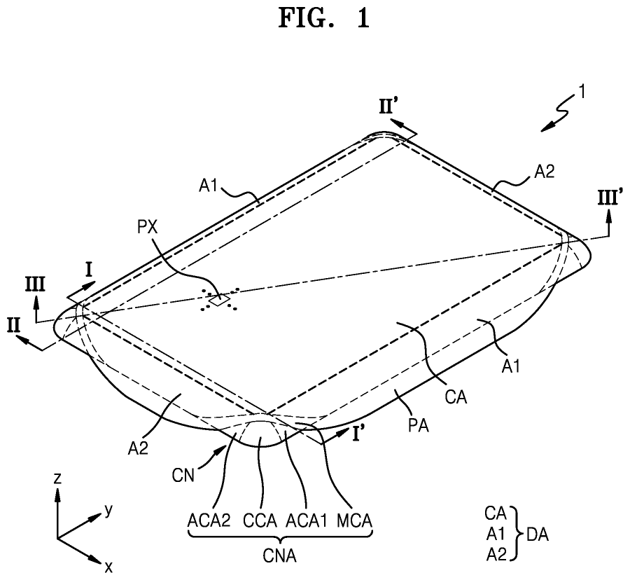

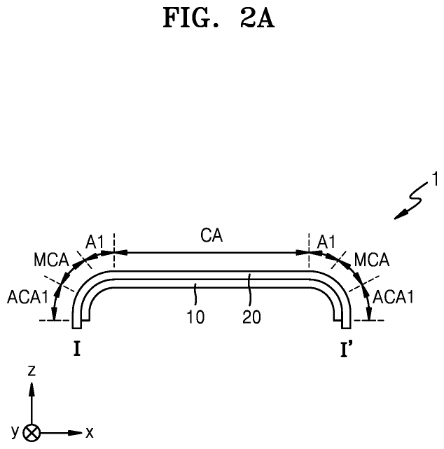

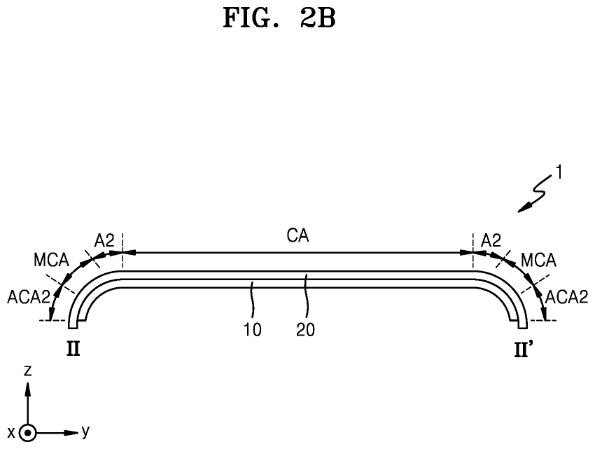

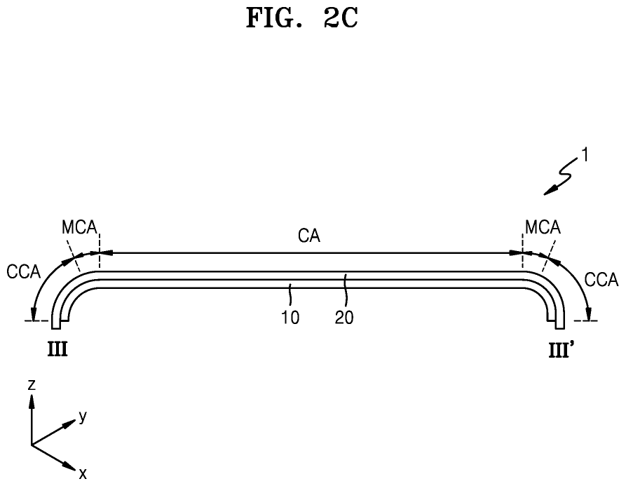

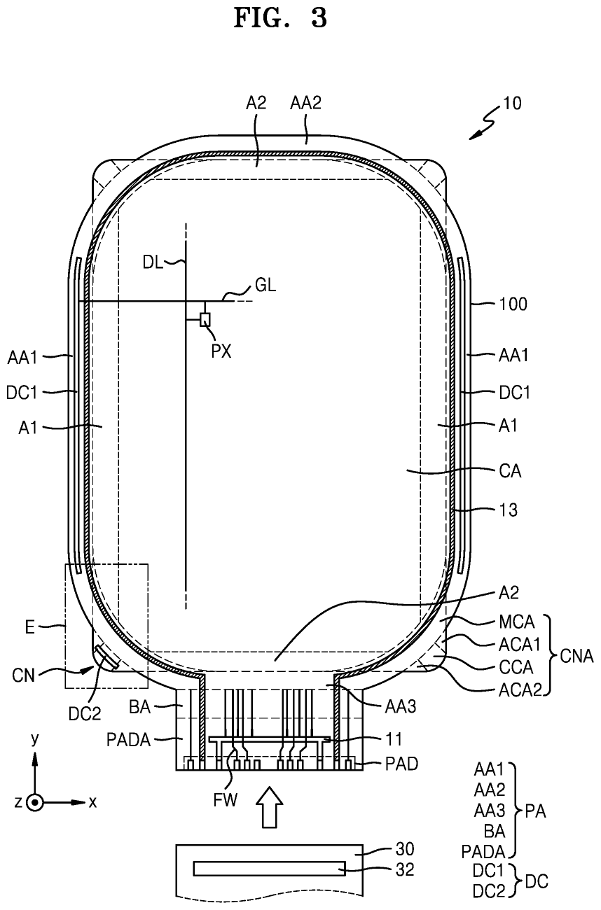

FIG. 1 is a perspective view schematically illustrating an embodiment of a display apparatus 1. FIG. 2A is a cross-sectional view illustrating the display apparatus 1 taken along line I-I′ of FIG. 1. FIG. 2B is a cross-sectional view illustrating the display apparatus 1 taken along line II-II′ of FIG. 1. FIG. 2C is a cross-sectional view illustrating the display apparatus 1 taken along line III-III′ of FIG. 1. FIG. 3 is a plan view schematically illustrating an embodiment of a display panel 10.

Referring to FIG. 1, the display apparatus 1 for displaying a moving image or a still image may be used as a display screen of not only a portable electronic device such as a mobile phone, a smartphone, a tablet personal computer, a mobile communication terminal, an electronic organizer, an electronic book, a portable multimedia player (“PMP”), a navigation device, or an ultra-mobile personal computer (“UMPC”) but also any of various products such as a television, a laptop computer, a monitor, an advertisement board, or an Internet of things (“IoT”) product. Also, the display apparatus 1 in an embodiment may be used in a wearable device such as a smart watch, a watch phone, a glasses-type display, or a head-mounted display (“HMD”). Also, the display apparatus 1 in an embodiment may be used as a center information display (“CID”) disposed on an instrument panel, a center fascia, or a dashboard of a vehicle, a room mirror display replacing a side-view mirror of a vehicle, or a display disposed on the back of a front seat for entertainment for a back seat of a vehicle.

Referring to FIGS. 1 through 3, the display apparatus 1 for displaying an image may have an edge extending in a first direction and an edge extending in a second direction. The first direction and the second direction may intersect each other. In an embodiment, an angle between the first direction and the second direction may be an acute angle, for example. In an alternative embodiment, an angle between the first direction and the second direction may be an obtuse angle or a right angle. For convenience of explanation, the following will be described assuming that the first direction and the second direction are perpendicular to each other. In an embodiment, the first direction may be an x direction or a −x direction, and the second direction may be a y direction or a −y direction, for example.

A corner CN where the edge extending in the first direction (e.g., the x direction or the −x direction) and the edge extending in the second direction (e.g., the y direction or the −y direction) meet each other may have a predetermined curvature.

The display apparatus 1 may include a display panel 10 and a cover window 20.

The display panel 10 may display an image. The display panel 10 may include a display area DA, a corner area CNA, and a peripheral area PA. The display area DA, the corner area CNA, and the peripheral area PA may be defined in a substrate 100 of the display panel 10. That is, the substrate 100 may include the display area DA, the corner area CNA, and the peripheral area PA.

The display area DA may include a central area CA, a first area A1, and a second area A2. The central area CA may be disposed at the center of the display apparatus 1. The central area CA may be a substantially flat area. The display apparatus 1 may provide most of images in the central area CA.

The first area A1 and the second area A2 may be disposed on side surfaces of the display panel 10. The first area A1 and the second area A2 may be also referred to as side display areas. Each of the first area A1 and the second area A2 may extend from a side of the central area CA.

The first area A1 may be adjacent to the central area CA in the first direction (e.g., the x direction or the −x direction). The first area A1 may extend in the second direction (e.g., the y direction or the −y direction). The display panel 10 may be bent in the first area A1. That is, the first area A1 may be defined as a bent area, unlike the central area CA, in a cross-section (e.g., a zx cross-section) in the first direction. In contrast, the first area A1 may not be bent in a cross-section (e.g., a yz cross-section) in the second direction. That is, the first area A1 may be an area bent about an axis extending in the second direction.

Although the first area A1 disposed in the x direction from the central area CA and the first area A1 disposed in the −x direction from the central area CA have the same curvature in FIG. 2A, the disclosure is not limited thereto. In an embodiment, the first area A1 disposed in the x direction from the central area CA and the first area A1 disposed in the −x direction from the central area CA may have different curvatures, for example.

The second area A2 may be adjacent to the central area CA in the second direction. The second area A2 may extend in the first direction. The display panel 10 may be bent in the second area A2. That is, the second area A2 may be defined as a bent area, unlike the central area CA, in the cross-section (e.g., the yz cross-section) in the second direction. In contrast, the second area A2 may not be bent in the cross-section (e.g., the zx cross-section) in the first direction. That is, the second area A2 may be an area bent about an axis extending in the first direction.

Although the second area A2 disposed in the y direction from the central area CA and the second area A2 disposed in the −y direction from the central area CA have the same curvature in FIG. 2B, the disclosure is not limited thereto. In an embodiment, the second area A2 disposed in the y direction from the central area CA and the second area A2 disposed in the −y direction from the central area CA may have different curvatures, for example.

The display panel 10 may be bent in the corner area CNA. The corner area CNA may be an area disposed at the corner CN. That is, the corner area CNA may be an area where the edge of the display apparatus 1 in the first direction and the edge of the display apparatus 1 in the second direction meet each other. The corner area CNA may extend from the corner of the central area CA. The corner area CNA may be disposed between the first area A1 and the second area A2 that are adjacent to each other. The corner area CNA may at least partially surround the central area CA, the first area A1, and the second area A2. In an embodiment, the corner CN may have a predetermined curvature. When the first area A1 extends in the first direction and is bent and the second area A2 extends in the second direction and is bent, at least a part of the corner area CNA may extend in the first direction and may be bent and may extend in the second direction and may be bent. At least a part of the corner area CNA may be an area where a plurality of curvatures in a plurality of directions overlaps each other. The display apparatus 1 may include a plurality of corner areas CNA. Four corner areas CNA are illustrated in FIGS. 1 and 3.

The corner area CNA may include a first corner area adjacent to the display area DA and a second corner area outside the first corner area. The first corner area may include an intermediate area MCA. The second corner area may include a central corner area CCA, a first adjacent area ACA1, and a second adjacent area ACA2.

The central corner area CCA may extend in the first direction and the second direction and may be bent. The central corner area CCA may be bent in the cross-section (e.g., the xz cross-section) in the first direction and in the cross-section (e.g., the yz cross-section) in the second direction. The central corner area CCA may be an area where curvatures in a plurality of directions overlaps each other. The central corner area CCA may be disposed between the first adjacent area ACA1 and the second adjacent area ACA2.

The first adjacent area ACA1 may be adjacent to the central corner area CCA. In an embodiment, the first adjacent area ACA1 may be disposed between the central corner area CCA and the first area A1. That is, at least a part of the first area A1 may be disposed between the central area CA and the first adjacent area ACA1 in the first direction. The first adjacent area ACA1 may be defined as the corner area CNA that is bent in the cross-section (e.g., the xz cross-section) in the first direction and that is not substantially bent in the cross-section (e.g., the yz cross-section) in the second direction.

The second adjacent area ACA2 may be adjacent to the central corner area CCA. In an embodiment, the second adjacent area ACA2 may be disposed between the central corner area CCA and the second area A2. That is, at least a part of the second area A2 may be disposed between the central area CA and the second adjacent area ACA2 in the second direction. The second adjacent area ACA2 may be defined as the corner area CNA that is bent in the cross-section (e.g., the yz cross-section) in the second direction, and is not substantially bent in the cross-section (e.g., the xz cross section) in the first direction.

The intermediate area MCA may be adjacent to the display area DA. The intermediate area MCA may be disposed between the central area CA and the central corner area CCA. In an embodiment, the intermediate area MCA may extend between the first area A1 and the first adjacent area ACA1. In an embodiment, the intermediate area MCA may extend between the second area A2 and the second adjacent area ACA2. In an embodiment, the intermediate area MCA may be bent.

A plurality of pixels PX may be disposed in at least one of the central area CA, the first area A1, and the second area A2. In an embodiment, although a plurality of pixels PX may be disposed in at least a part of the corner area CNA, the disclosure is not limited thereto. Each of the plurality of pixels PX may be connected to a gate line GL and a data line DL, and may include a display element. In an embodiment, the display element may be an organic light-emitting diode including an organic emission layer. In an alternative embodiment, the display element may be a light-emitting diode including an inorganic emission layer. The light-emitting diode may have a micro-scale or nano-scale size. In an embodiment, the light-emitting diode may be a micro light-emitting diode, for example. In an alternative embodiment, the light-emitting diode may be a nanorod light-emitting diode. The nanorod light-emitting diode may include gallium nitride (GaN). In an embodiment, a color conversion layer may be disposed on the nanorod light-emitting diode. The color conversion layer may include quantum dots. In an alternative embodiment, the display element may be a quantum dot light-emitting diode including a quantum dot emission layer.

Each of the pixels PX may emit light of a predetermined color by the display element. In the specification, the pixel PX may refer to an emission area as a minimum unit for providing an image. Accordingly, in the specification, an arrangement of the pixels may refer to an arrangement of display elements or an arrangement of emission areas. When an organic light-emitting diode is employed as the display element, an emission area may be defined by an opening of a pixel-defining layer, which will be described below.

The peripheral area PA may be disposed outside the display area DA. The pixel PX may not be disposed in the peripheral area PA. Accordingly, the peripheral area PA may be a non-display area where an image is not displayed. The peripheral area PA may include a first peripheral area AA1, a second peripheral area AA2, a third peripheral area AA3, a bending area BA, and a pad area PADA.

The first peripheral area AA1 may be disposed outside the first area A1. The first area A1 may be disposed between the first peripheral area AA1 and the central area CA. The central area CA may be disposed between a pair of first peripheral areas AA1 facing each other. In an embodiment, the first peripheral area AA1 may extend from the first area A1 in the first direction.

The second peripheral area AA2 may be disposed outside the upper second area A2, and the upper second area A2 may be disposed between the second peripheral area AA2 and the central area CA. The third peripheral area AA3 may be disposed outside the lower second area A2, and the lower second area A2 may be disposed between the third peripheral area AA3 and the central area CA. The second peripheral area AA2 and the third peripheral area AA3 may extend in the second direction. The central area CA may be disposed between the second peripheral area AA2 and the third peripheral area AA3.

A driving circuit DC for providing an electrical signal to the pixel PX and input lines for providing an electrical signal to the driving circuit DC may be disposed in the peripheral area PA and the corner area CNA. In an embodiment, the driving circuit DC may be a gate driving circuit for providing a gate signal to each pixel PX through the gate line GL. The input lines may include at least one clock line for providing at least one clock signal and at least one voltage line for providing at least one voltage signal. In an embodiment, the driving circuit DC may be a data driving circuit for providing a data signal to each pixel PX through the data line DL. A voltage supply line for providing a power supply voltage to the pixel PX may be further disposed in the peripheral area PA and the corner area CNA. The voltage supply line may include a first voltage supply line 11 and a second voltage supply line 13. In an embodiment, the driving circuit DC and/or the input lines may be disposed in the first peripheral area AA1, the central corner area CCA, the first adjacent area ACA1, and the second adjacent area ACA2.

The driving circuit DC may include a first driving circuit DC1 disposed in the first peripheral area AA1 of the display panel 10 and a second driving circuit DC2 disposed in the corner area CNA. In an embodiment, the driving circuit DC may be disposed closer to an outer edge of the display panel 10 than the second voltage supply line 13 is.

The first driving circuit DC1 may be disposed in the first peripheral area AA1. Although the first driving circuit DC1 is disposed closer to an edge of the display panel 10 than the second voltage supply line 13 is in an embodiment, the disclosure is not limited thereto. In another embodiment, the first driving circuit DC1 may be disposed closer to the central area CA than the second voltage supply line 13 is to the central area CA.

The second driving circuit DC2 may be disposed in the central corner area CCA, the first adjacent area ACA1, and the second adjacent area ACA2. The second driving circuit DC2 may be disposed closer to an edge of the display panel 10 than the second voltage supply line 13 is to the edge of the display panel 10.

The bending area BA may be disposed outside the second area A2. The bending area BA may be disposed outside the third peripheral area AA3. The third peripheral area AA3 may be disposed between the bending area BA and the central area CA. The display panel 10 may be bent in the bending area BA. In this case, the pad area PADA may face a rear surface of the display panel 10 opposite to a top surface on which an image is displayed. Accordingly, the pad area PADA may not be visible to a user.

The pad area PADA may be disposed outside the bending area BA. The bending area BA may be disposed between the third peripheral area AA3 and the pad area PADA. A terminal unit PAD may be disposed in the pad area PADA. The terminal unit PAD may be exposed without being covered by an insulating layer, and may be electrically connected to a display circuit board 30. A display driver 32 may be disposed on the display circuit board 30 The display driver 32 may generate a control signal transmitted to the driving circuit DC. The display driver 32 may generate a data signal, and the generated data signal may be transmitted to pixel circuits through the data line DL. The display driver 32 may supply a driving voltage ELVDD to the first voltage supply line 11, and may supply a common voltage ELVSS to the second voltage supply line 13. The first voltage supply line 11 may be disposed below the display area DA and may extend in the x direction. In an embodiment, a signal wire FW extending in the bending area BA and the pad area PADA may be connected to pads of the terminal unit PAD.

The second voltage supply line 13 may have a loop shape with an open side, and may partially surround the display area DA. The second voltage supply line 13 may be disposed along the first peripheral area A1, the second peripheral area AA2, and the corner area CNA. In an embodiment, the second voltage supply line 13 may be disposed between the driving circuit DC and the central area CA. That is, the second voltage supply line 13 may be disposed closer to the central area CA than the driving circuit DC is. The second voltage supply line 13 may be disposed between the first driving circuit DC1 and the central area CA, and may be disposed between the second driving circuit DC2 and the central area CA. In an embodiment, in the first peripheral area AA1, the second voltage supply line 13 may be disposed closer to the central area CA than the first driving circuit DC1 is to the central area CA. In the corner area CNA, the second voltage supply line 13 may be disposed closer to the central area CA than the second driving circuit DC2 is to the central area CA.

The display panel 10 may be disposed under the cover window 20. The display panel 10 may be attached to the cover window 20 by an optically clear adhesive (“OCA”) (not shown).

The cover window 20 may protect the display panel 10. In an embodiment, the cover window 20 may be disposed on the display panel 10. In an embodiment, the cover window 20 may be a flexible window. The cover window 20 may be easily bent by an external force to protect the display panel 10. The cover window 20 may include glass, sapphire, or plastic. The cover window 20 may include ultra-thin glass. In an alternative embodiment, the cover window 20 may include transparent polyimide.

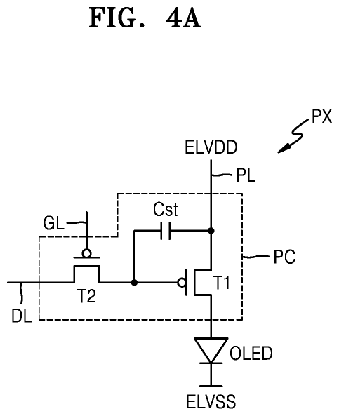

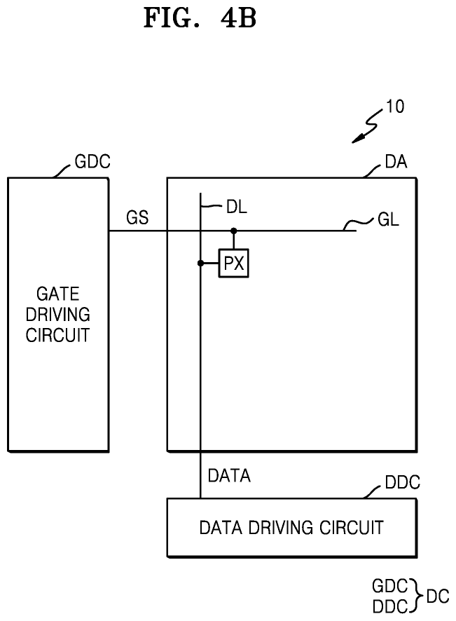

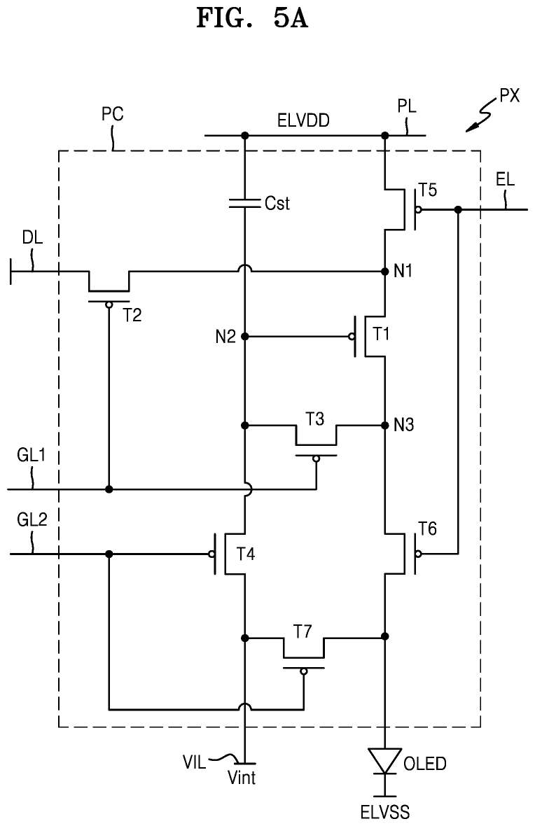

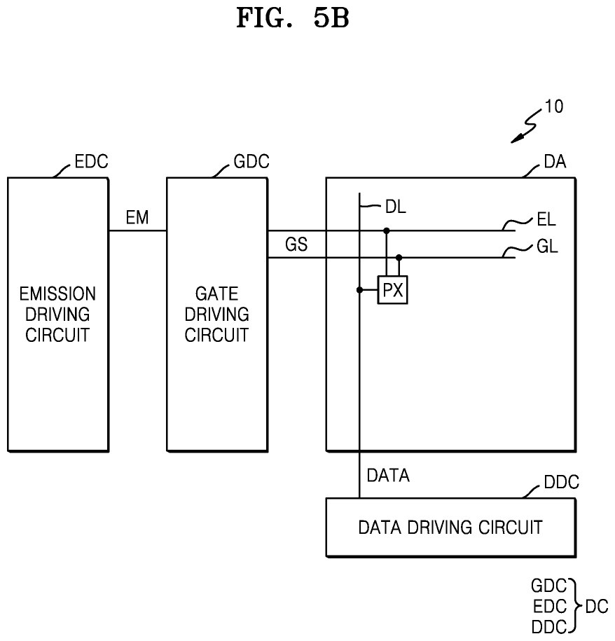

FIGS. 4A and 5A are each a circuit diagram illustrating an embodiment of a pixel. FIGS. 4B and 5B are each a configuration diagram schematically illustrating an embodiment of a display panel.

Referring to FIG. 4A, the pixel PX includes a pixel circuit PC, and an organic light-emitting diode OLED connected to the pixel circuit PC. The pixel circuit PC may include a first transistor T1, a second transistor T2, and a capacitor Cst. Each pixel PX may emit, red, green, blue, or white light, for example, through the organic light-emitting diode OLED. Each of the first transistor T1 and the second transistor T2 may be a thin-film transistor.

The second transistor T2 that is a switching transistor may be connected to the gate line GL and the data line DL, and may transmit a data signal input from the data line DL to the first transistor T1 in response to a gate signal input from the gate line GL. The capacitor Cst may be connected to the second transistor T2 and a driving voltage line PL, and may store a voltage corresponding to a difference between a voltage corresponding to the data signal received from the second transistor T2 and a driving voltage ELVDD supplied to the driving voltage line PL.

The first transistor T1 that is a driving transistor may be connected to the driving voltage line PL and the capacitor Cst, and may control driving current flowing from the driving voltage line PL to the organic light-emitting diode OLED in response to a value of the voltage stored in the capacitor Cst. The organic light-emitting diode OLED may emit light having a predetermined luminance due to the driving current. A counter electrode of the organic light-emitting diode OLED may receive a common voltage ELVSS.

Referring to FIG. 4B, a plurality of pixels PX and signal lines for applying an electrical signal to the plurality of pixels PX may be disposed in the display area DA. The signal lines for applying an electrical signal to each of the pixels PX may include a plurality of data lines DL and a plurality of gate lines GL.

The driving circuit DC for providing a signal for driving the pixels PX may be disposed outside the display area DA. The driving circuit DC may include a gate driving circuit GDC and a data driving circuit DDC. In an embodiment, the gate driving circuit GDC may be disposed in the first peripheral area AA1, the central corner area CCA, the first adjacent area ACA1, and the second adjacent area ACA2. The gate driving circuit GDC may be disposed along an outside of an edge of the display area DA, e.g., the first peripheral area AA1 and the intermediate area MCA. The gate driving circuit GDC may be connected to the gate lines GL, and may output a gate signal GS to the gate lines GL. The data driving circuit DDC may be disposed in the pad area PADA. The data driving circuit DDC may be connected to the data lines DL, and may output a data signal DATA to the data lines DL.

Although the pixel circuit PC includes two transistors and one capacitor in FIG. 4A, the disclosure is not limited thereto. The number of transistors and the number of capacitors may be changed in various ways according to a design of the pixel circuit PC.

Referring to FIG. 5A, the pixel circuit PC may include a first transistor T1 that is a driving transistor and second through seventh transistors T2 through T7 that are switching transistors. According to a type (e.g., a p-type or an n-type) and an operation condition of a transistor, a first terminal of each of the first through seventh transistors T1 through T7 may be a source terminal or a drain terminal and a second terminal of each transistor may be a terminal different from the first terminal. In an embodiment, when the first terminal is a source terminal, the second terminal may be a drain terminal, for example. In an embodiment, a source terminal and a drain terminal may be interchangeably used with a source electrode and a drain electrode, respectively.

The pixel circuit PC may be connected to a first gate line GL1 that transmits a first gate signal, a second gate line GL2 that transmits a second gate signal, an emission control line EL that transmits an emission control signal, a data line DL that transmits a data signal, a driving voltage line PL that transmits a driving voltage ELVDD, and an initialization voltage line VIL that transmits an initialization voltage Vint.

The first transistor T1 may be connected between the driving voltage line PL and an organic light-emitting diode OLED. The first transistor T1 may be connected to the driving voltage line PL via the fifth transistor T5, and may be electrically connected to the organic light-emitting diode OLED via the sixth transistor T6. The first transistor T1 includes a gate connected to a second node N2, a first terminal connected to a first node N1, and a second terminal connected to a third node N3. The first transistor T1 may receive a data signal according to a switching operation of the second transistor T2, and may supply driving current to the organic light-emitting diode OLED.

The second transistor T2 (data write transistor) may be connected between the data line DL and the first node N1, and may be connected to the driving voltage line PL via the fifth transistor T5. The first node N1 may be a node to which the first transistor T1 and the fifth transistor T5 are connected. The second transistor T2 includes a gate connected to the first gate line GL1, a first terminal connected to the data line DL, and a second terminal connected to the first node N1 (or the first terminal of the first transistor T1). The second transistor T2 may be turned on according to the first gate signal received through the first gate line GL1, and may perform a switching operation of transmitting the data signal transmitted through the data line DL to the first node N1.

The third transistor T3 (compensation transistor) may be connected between the second node N2 and the third node N3. The third transistor T3 may be connected to the organic light-emitting diode OLED via the sixth transistor T6. The second node N2 may be a node to which the gate of the first transistor T1 is connected, and the third node N3 may be a node to which the first transistor T1 and the sixth transistor T6 are connected. The third transistor T3 includes a gate connected to the first gate line GL1, a first terminal connected to the second node N2 (or the gate of the first transistor T1), and a second terminal connected to the third node N3 (or the second terminal of the first transistor T1). The third transistor T3 may be turned on according to the first gate signal received through the first gate line GL1, and may compensate for a threshold voltage of the first transistor T1 by diode-connecting the first transistor T1.

The fourth transistor T4 (first initialization transistor) may be connected between the second node N2 and the initialization voltage line VIL. The fourth transistor T4 includes a gate connected to the second gate line GL2, a first terminal connected to the second node N2, and a second terminal connected to the initialization voltage line VIL. The fourth transistor T4 may be turned on according to the second gate signal received through the second gate line GL2, and may initialize a gate voltage of the first transistor T1 by transmitting the initialization voltage Vint to the gate of the first transistor T1.

The fifth transistor T5 (first emission control transistor) may be connected between the driving voltage line PL and the first node N1. The sixth transistor T6 (second emission control transistor) may be connected between the third node N3 and the organic light-emitting diode OLED. The fifth transistor T5 includes a gate connected to the emission control line EL, a first terminal connected to the driving voltage line PL, and a second terminal connected to the first node N1. The sixth transistor T6 includes a gate connected to the emission control line EL, a first terminal connected to the third node N3, and a second terminal connected to a pixel electrode of the organic light-emitting diode OLED. The fifth transistor T5 and the sixth transistor T6 are simultaneously turned on according to the emission control signal received through the emission control line EL, and driving current flows through the organic light-emitting diode OLED.

The seventh transistor T7 (second initialization transistor) may be connected between the organic light-emitting diode OLED and the initialization voltage line VIL. The seventh transistor T7 includes a gate connected to the second gate line GL2, a first terminal connected to the second terminal of the sixth transistor T6 and the pixel electrode of the organic light-emitting diode OLED, and a second terminal connected to the initialization voltage line VIL. The seventh transistor T7 may be turned on according to the second gate signal received through the second gate line GL2, and may initialize a voltage of the pixel electrode of the organic light-emitting diode OLED by transmitting the initialization voltage Vint to the pixel electrode of the organic light-emitting diode OLED. In another embodiment, the gate of the seventh transistor T7 may be connected to a third gate line separate from the second gate line GL2. In an alternative embodiment, the seventh transistor T7 may be omitted.

A capacitor Cst includes a first electrode connected to the second node N2 and a second electrode connected to the driving voltage line PL. The capacitor Cst may maintain a voltage applied to the gate electrode of the first transistor T1 by storing and maintaining a voltage corresponding to a difference between voltages supplied to opposite ends of the first electrode and the second electrode.

The organic light-emitting diode OLED may include the pixel electrode (e.g., an anode) and a counter electrode (e.g., a cathode) facing the pixel electrode, and the counter electrode may receive a common voltage ELVSS. The organic light-emitting diode OLED may display an image by receiving driving current corresponding to a value of the voltage stored in the capacitor Cst from the first transistor T1 and emitting light in a predetermined color.

Referring to FIG. 5B, a plurality of pixels PX and signal lines for applying an electrical signal to the plurality of pixels PX may be disposed in the display area DA. The signal lines for applying an electrical signal to each of the pixels PX may include a plurality of data lines DL, a plurality of gate lines GL, and a plurality of emission control lines EL.

The driving circuit DC for providing a signal for driving the pixels PX may be disposed outside the display area DA. The driving circuit DC may include a gate driving circuit GDC, an emission driving circuit EDC, and a data driving circuit DDC. In an embodiment, the gate driving circuit GDC and the emission driving circuit EDC may be disposed in the first peripheral area AA1, the central corner area CCA, the first adjacent area ACA1, and the second adjacent area ACA2. The gate driving circuit GDC and the emission driving circuit EDC may be disposed adjacent and parallel to each other, and may be disposed along an edge of the display area DA, e.g., the first peripheral area AA1 and the intermediate area MCA. The gate driving circuit GDC may be connected to the gate lines GL, and may output a gate signal GS to the gate lines GL. The emission driving circuit EDC may be connected to the emission control lines EL, and may output an emission control signal EM to the emission control lines EL. The data driving circuit DDC may be disposed in the pad area PADA. The data driving circuit DDC may be connected to the data lines DL, and may output a data signal DATA to the data lines DL.

Although transistors of the pixel circuit are P-type transistors in FIGS. 5A and 5B, the disclosure is not limited thereto. In an embodiment, in various embodiments, transistors of the pixel circuit may be N-type transistors, or some may be P-type transistors and others may be N-type transistors, for example.

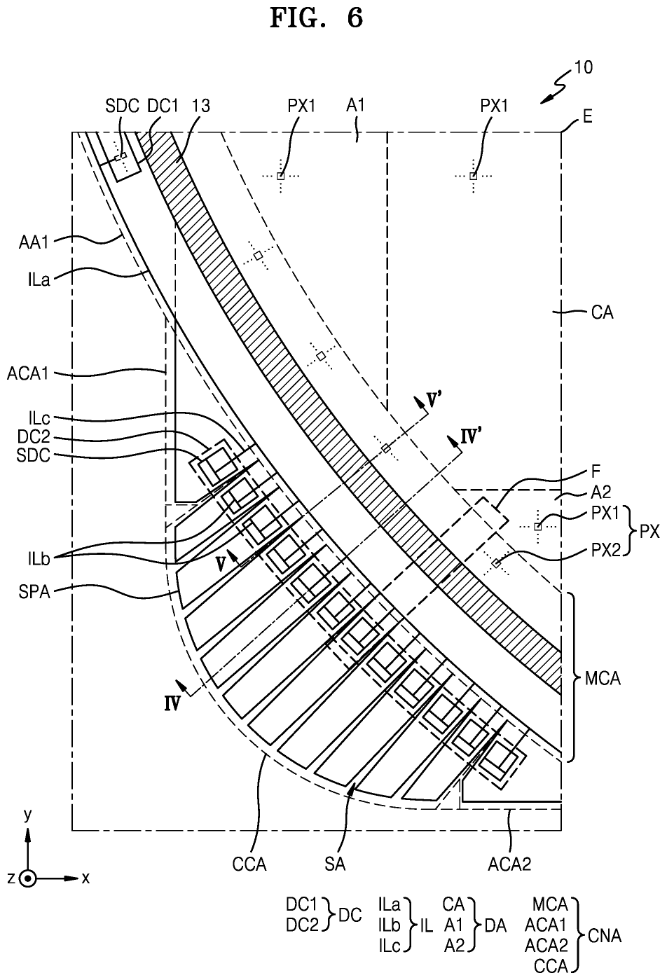

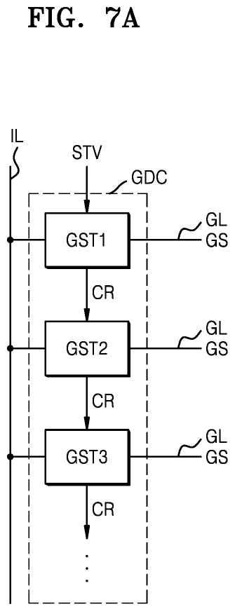

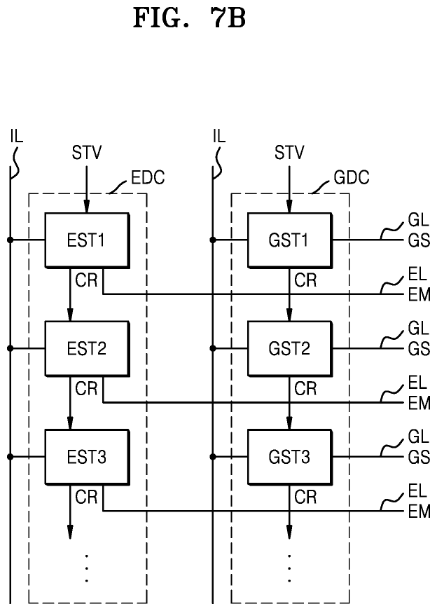

FIG. 6 is an enlarged view schematically illustrating a portion E of FIG. 3. FIGS. 7A and 7B are each a diagram schematically illustrating an embodiment of a driving circuit.

Referring to FIG. 6, the display panel 10 may include the plurality of pixels PX, the driving circuit DC, an input line IL, and the second voltage supply line 13 disposed between the driving circuit DC and the display area DA.

The corner area CNA may include the intermediate area MCA, the central corner area CCA, the first adjacent area ACA1, and the second adjacent area ACA2.

The central corner area CCA may include a linear extending area SPA. In an embodiment, the central corner area CCA may include a plurality of extending areas SPA that are spaced apart from each other. Each of the plurality of extending areas SPA may be an area starting from a boundary between the intermediate area MCA and the central corner area CCA extending in a direction away from the central area CA (hereinafter, also referred to as an ‘extending direction of the extending area SPA’). In an embodiment, each of the plurality of extending areas SPA may extend in a predetermined direction between the first direction and the second direction.

A separation area SA may be defined between adjacent extending areas SPA. The separation area SA may be an area where an element of the display panel 10 is not disposed. When the central corner area CCA is bent, compressive strain may be greater than tensile strain in the central corner area CCA. Because the separation area SA is defined between adjacent extending areas SPA in the illustrated embodiment, the central corner area CCA may be contracted. Accordingly, the display panel 10 may be bent without damaging the central corner area CCA.

In an embodiment, the plurality of pixels PX may be disposed in the display area DA and at least a portion of the corner area CNA. In an embodiment, a first pixel PX1 may be disposed in the display area DA, and a second pixel PX2 may be disposed in the corner area CNA. Although the second pixel PX2 may be disposed in the intermediate area MCA in an embodiment, the disclosure is not limited thereto.

The driving circuit DC may be spaced apart from the display area DA with the second voltage supply line 13 therebetween. In an embodiment, the driving circuit DC may be spaced apart from the central area CA with the second voltage supply line 13 therebetween. The driving circuit DC may include the first driving circuit DC1 and the second driving circuit DC2. The first driving circuit DC1 may be disposed in the first peripheral area AA1. The second driving circuit DC2 may be disposed in the first adjacent area ACA1, the second adjacent area ACA2, and the extending area SPA. The second driving circuit DC2 may not be disposed in the separation area SA.

The driving circuit DC may include a plurality of sub-driving circuits SDC. The plurality of sub-driving circuits SDC may be arranged along an edge of the first area A1 in the first peripheral area AA1, and may be arranged along an edge of the intermediate area MCA in the central corner area CCA, the first adjacent area ACA1, and the second adjacent area ACA2. The sub-driving circuits SDC of the central corner area CCA, the first adjacent area ACA1, and the second adjacent area ACA2 may be arranged to at least partially surround the intermediate area MCA.

In an embodiment, the driving circuit DC may include the gate driving circuit GDC. Referring to FIG. 7A, the gate driving circuit GDC may be implemented as a shift register including a plurality of stages GST1, GST2, GST3, etc. Each of the stages GST1, GST2, GST3, etc., may be the sub-driving circuit SDC. Each of the stages GST1, GST2, GST3, etc., may be connected to a corresponding gate line GL, and may output a gate signal GS to the corresponding gate line GL. The first stage GST1 may output a gate signal GS in response to an external start signal STV, and each of the remaining stages GST2, GST3, etc., other than the first stage GST1 may receive a carry signal CR output from a previous stage as a start signal. The stages GST1, GST2, GST3, etc., may be respectively connected to a plurality of input lines IL arranged outside the stages GST1, GST2, GST3, etc.

In an embodiment, the driving circuit DC may include a plurality of driving circuits. In an embodiment, the driving circuit DC may include the gate driving circuit GDC and the emission driving circuit EDC, for example. Some of the input lines IL connected to the gate driving circuit GDC may input the same signal as that of some of the input lines IL connected to the emission driving circuit EDC.

Referring to FIG. 7B, the gate driving circuit GDC may be implemented as a shift register including a plurality of stages GST1, GST2, GST3, etc. Each of the stages GST1, GST2, GST3, etc., may be the sub-driving circuit SDC. Each of the stages GST1, GST2, GST3, etc., may be connected to a corresponding gate line GL, and may output a gate signal GS to the corresponding gate line GL. The first stage GST1 may output a gate signal GS in response to an external start signal STV, and each of the remaining stages GST2, GST3, etc., other than the first stage GST1 may receive a carry signal CR output from a previous stage as a start signal. The stages GST1, GST2, GST3, etc., may be connected to a plurality of input lines IL arranged outside the stages GST1, GST2, GST3, etc.

The emission driving circuit EDC may be implemented as a shift register including a plurality of stages EST1, EST2, EST3, etc. Each of the stages EST1, EST2, EST3, etc., may be the sub-driving circuit SDC. Each of the stages EST1, EST2, EST3, etc., may be connected to a corresponding emission control line EL, and may output an emission control signal EM to the corresponding emission control line EL. The first stage EST1 may output an emission control signal EM in response to an external start signal STV, and each of the remaining stages EST2, EST3, etc., other than the first stage EST1 may receive a carry signal CR output from a previous stage as a start signal. The stages EST1, EST2, EST3, etc., may be connected to a plurality of input lines IL arranged outside the stages EST1, EST2, EST3, etc.

The plurality of input lines IL may be signal lines including a plurality of voltage lines and a plurality of clock lines. For convenience of explanation, only one input line is illustrated in FIGS. 7A and 7B.

Although each of the stages GST1, GST2, GST3, etc., is connected to one gate line GL in the gate driving circuit GDC in FIGS. 7A and 7B, this is merely one of embodiments. Each of the stages GST1, GST2, GST3, etc., may be connected to one or more gate lines GL, and may output a gate signal GS at a determined timing to each gate line GL.

Referring back to FIG. 6, the input lines IL may include a first input line ILa, a second input line ILb, a and a third input line ILc that connects the first input line ILa to the second input line ILb. In an embodiment, each of the plurality of input lines IL may be spaced apart from the central area CA with the second voltage supply line 13 therebetween. That is, each of the first input line ILa, the second input line ILb, and the third input line ILc may be spaced apart from the central area CA with the second voltage supply line 13 therebetween.

The first input line ILa may extend along edges of the first peripheral area AA1 and the intermediate area MCA in the first peripheral area AA1 and the intermediate area MCA. The first input line ILa may extend to at least partially surround the central area CA, the first area A1, and the second area A2. The first input line ILa may be connected to the first driving circuit DC1 arranged in the first peripheral area AA1. The first input line ILa may be disposed adjacent to outer sides of the sub-driving circuits SDC. The first input line ILa may be spaced apart from the central area CA with the second voltage supply line 13 therebetween. The first input line ILa may be disposed between the second voltage supply line 13 and the second driving circuit DC2.

The second input line ILb may be disposed in the central corner area CCA, the first adjacent area ACA1, and the second adjacent area ACA2. The second input line ILb may extend to surround an edge of the intermediate area MCA. The second input line ILb disposed in the first adjacent area ACA1, the second input line ILb disposed in the central corner area CCA, and the second input line ILb disposed in the second adjacent area ACA2 may be separated from each other and may not be disposed in the separation area SA. The second input line ILb may be connected to the sub-driving circuits SDC arranged in the central corner area CCA, the first adjacent area ACA1, and the second adjacent area ACA2. The second input line ILb may be spaced apart from the central area CA with the second voltage supply line 13 therebetween.

The third input line ILc may electrically connect the first input line ILa to the second input line ILb. An extending direction of the third input line ILc may be different from extending directions of the first input line ILa and the second input line ILb. In an embodiment, the third input line ILc may extend in a direction perpendicular to the extending directions of the first input line ILa and the second input line ILb, for example. The third input line ILc may extend away from the intermediate area MCA. Although the second input line ILb is disposed in the second driving circuit DC2, the disclosure is not limited thereto, and may be disposed outside the second driving circuit DC2.

A plurality of third input lines ILc may be provided. The plurality of third input lines ILc may be disposed in the corner area CNA. The third input lines ILc may extend from a portion connected to the first input line ILa of the intermediate area MCA to the central corner area CCA, and may each be disposed in the extending area SPA. The third input lines ILc may extend from a portion connected to the first input line ILa of the intermediate area MCA to the first adjacent area ACA1, and may be disposed in the first adjacent area ACA1. The third input lines ILc may extend from a portion connected to the first input line ILa of the intermediate area MCA to the second adjacent area ACA2, and may be disposed in the second adjacent area ACA2.

The second voltage supply line 13 may be disposed in the intermediate area MCA. The second voltage supply line 13 may be disposed between the extending area SPA and the central area CA. The second voltage supply line 13 may be disposed between the central area CA and the first driving circuit DC1. The second voltage supply line 13 may be disposed between the central area CA and the second driving circuit DC2.

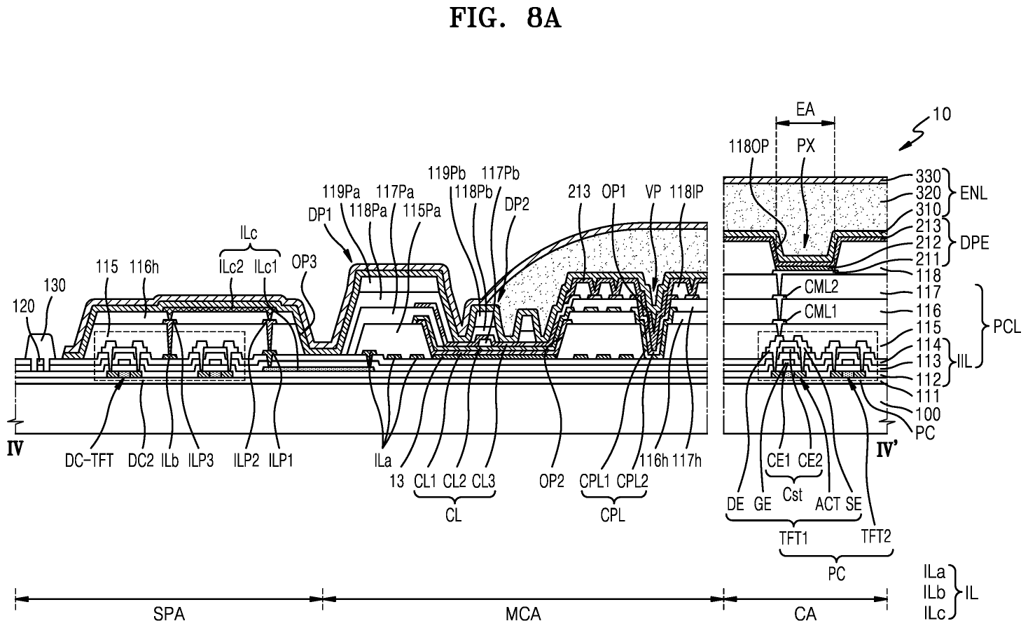

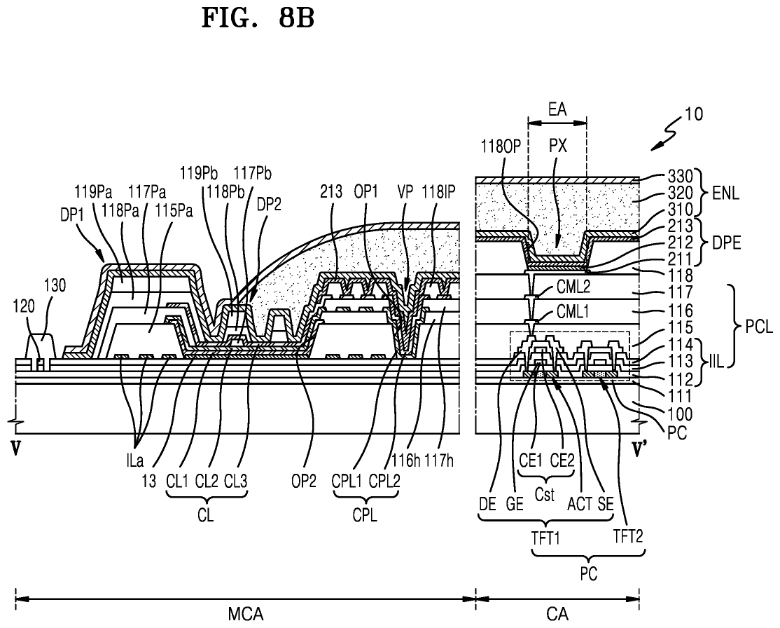

FIG. 8A is a cross-sectional view schematically illustrating an embodiment of a display panel, taken along line IV-IV′ of FIG. 6. FIG. 8B is a cross-sectional view schematically illustrating an embodiment of a display panel, taken along line V-V′ of FIG. 6.

Referring to FIGS. 8A and 8B, the display panel 10 may include the substrate 100, a buffer layer 111, a circuit layer PCL, a display element DPE, and a thin-film encapsulation layer ENL. The display panel 10 may further include a valley portion VP, a first dam DP1, a second dam DP2, and a crack-preventing dam 120.

In a cross-sectional view, in a direction from the central area CA to the extending area SPA, the second voltage supply line 13, the input line IL, and the second driving circuit DC2 may be sequentially arranged. In a cross-sectional view, in a direction from the central area CA to the extending area SPA, the second voltage supply line 13, the first dam DP1, the second driving circuit DC2, and the crack-preventing dam 120 may be sequentially arranged.

The second driving circuit DC2 may be disposed between the crack-preventing dam 120 and the first dam DP1. The second driving circuit DC2 may be spaced apart from the central area CA with the first dam DP1 therebetween. The second driving circuit DC2 may be spaced apart from the central area CA with the second voltage supply line 13 therebetween. The second driving circuit DC2 may be spaced apart from the central area CA with the valley portion VP therebetween. The second voltage supply line 13 may be disposed between the second driving circuit DC2 and the valley portion VP. The first dam DP1 may be disposed between the second driving circuit DC2 and the valley portion VP. According to the disclosure, because the second driving circuit DC2 is disposed in the extending area SPA and is disposed closer to an outer edge of the display panel 10 than the second voltage supply line 13 is to the outer edge of the display panel 10, display areas for displaying an image may be further increased.

The buffer layer 111 may be disposed on the substrate 100. The buffer layer 111 may include an inorganic insulating material such as silicon nitride (SiNx), silicon oxynitride (SiOxNy), or silicon oxide (SiOx), and may have a single or multi-layer structure including the inorganic insulating material.

The circuit layer PCL may be disposed on the buffer layer 111. The circuit layer PCL may include the pixel circuit PC and the driving circuit DC (refer to FIG. 6). The pixel circuit PC may be disposed in the central area CA. Although the pixel circuit PC is disposed in the central area CA in FIGS. 8A and 8B, the pixel circuit PC may be disposed in the display area DA (refer to FIG. 6) including the first area A1 (refer to FIG. 6) and the second area A2 (refer to FIG. 6). The pixel circuit PC may include a first thin-film transistor TFT1, a second thin-film transistor TFT2, and a storage capacitor Cst. Although the first thin-film transistor TFT1 may be a driving transistor and the second thin-film transistor TFT2 may be a switching transistor for the pixel circuit PC, the disclosure is not limited thereto. The driving circuit DC (refer to FIG. 6) may include a driving circuit transistor DC-TFT. The second driving circuit DC2 is illustrated in FIG. 8A. The second driving circuit DC2 may be disposed in the extending area SPA. As shown in FIG. 8B, the second driving circuit DC2 may not be disposed in a cross-sectional view along the separation area SA.

The circuit layer PCL may include an inorganic insulating layer IIL disposed under and/or over elements of the first thin-film transistor TFT1, a lower insulating layer 115, a first insulating layer 116, and a first upper insulating layer 117. The inorganic insulating layer IIL may include a first gate insulating layer 112, a second gate insulating layer 113, and an inter-insulating layer 114. The inorganic insulating layer IIL may be disposed between the substrate 100 and an organic insulating layer. Each of the first thin-film transistor TFT1, the second thin-film transistor TFT2, and the driving circuit transistor DC-TFT may include a semiconductor layer ACT, a gate electrode GE, a source electrode SE, and a drain electrode DE.

The semiconductor layer ACT may include polysilicon. In an alternative embodiment, the semiconductor layer ACT may include amorphous silicon, an oxide semiconductor, or an organic semiconductor. The semiconductor layer ACT may include a channel region, and a drain region and a source region disposed on opposite sides of the channel region. The gate electrode GE may overlap the channel region.

The gate electrode GE may include a low-resistance metal material. The gate electrode GE may include a conductive material including molybdenum (Mo), aluminum (Al), copper (Cu), or titanium (Ti), and may have a single or multi-layer structure including the above material.

The first gate insulating layer 112 between the semiconductor layer ACT and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). ZnOₓ may be ZnO and/or ZnO₂.

The inter-insulating layer 114 may cover an upper electrode CE2. The inter-insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The inter-insulating layer 114 may have a single or multi-layer structure including the above inorganic insulating material.

Each of the drain electrode DE and the source electrode SE may be disposed on the inter-insulating layer 114. Each of the drain electrode DE and the source electrode SE may include a material having excellent conductivity. Each of the drain electrode DE and the source electrode SE may include a conductive material including molybdenum (Mo), aluminum (Al), copper (Cu), or titanium (Ti), and may have a single or multi-layer structure including the above material. In an embodiment, each of the drain electrode DE and the source electrode SE may have a multi-layer structure including Ti/Al/Ti.

The second gate insulating layer 113 may cover the gate electrode GE. The second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO), like the first gate insulating layer 112.

The upper electrode CE2 of the storage capacitor Cst may be disposed on the second gate insulating layer 113. The upper electrode CE2 may overlap the gate electrode GE that is disposed below the upper electrode CE2. In this case, the gate electrode GE of the first thin-film transistor TFT1 and the upper electrode CE2 overlapping each other with the second gate insulating layer 113 therebetween may constitute the storage capacitor Cst. That is, the gate electrode GE of the first thin-film transistor TFT1 may function as a lower electrode CE1 of the storage capacitor Cst. The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure including the above material.

The inter-insulating layer 114 may cover the upper electrode CE2. The inter-insulating layer 114 may include silicon oxide (SiOx), silicon nitride (SiNₓ), silicon oxynitride (SiOxNy), aluminum oxide (Al₂O₃), titanium oxide (TiO₂), tantalum oxide (Ta₂O₅), hafnium oxide (HfO₂), or zinc oxide (ZnO). The inter-insulating layer 114 may have a single or multi-layer structure including the above inorganic insulating material.

Although not shown, the gate line GL and the emission control line EL may be disposed between the first gate insulating layer 112 and the second gate insulating layer 113 and/or between the second gate insulating layer 113 and the inter-insulating layer 114.

Each of the drain electrode DE and the source electrode SE may be disposed on the inter-insulating layer 114. Each of the drain electrode DE and the source electrode SE may include a conductive material including molybdenum (Mo), aluminum (Al), copper (Cu), or titanium (Ti), and may have a single or multi-layer structure including the above material. In an embodiment, each of the drain electrode DE and the source electrode SE may have a multi-layer structure including Ti/Al/Ti.

The first input line ILa and the second input line ILb may be disposed on the inter-insulating layer 114. The first input line ILa and the second input line ILb may be disposed in the same layer. Although the first input line ILa and the second voltage supply line 13 are disposed in the same layer, the disclosure is not limited thereto. The second input line ILb may be disposed in the same layer as the second voltage supply line 13. The first input line ILa may overlap the first dam DP1.

The third input line ILc may include a 3-1^{st} input line ILc1 and a 3-2^{nd} input line ILc2. The third input line ILc may be disposed in a different layer from the first input line ILa and the second input line ILb.

The 3-1^{st} input line ILc1 may be disposed in a layer of a level lower than that of the first input line ILa. The 3-1^{st} input line ILc1 may be disposed in a layer of a level lower than that of the second input line ILb. A level in the disclosure may be defined as a vertical level indicating a distance in a direction perpendicular to the substrate 100 from a top surface of the substrate 100. The 3-1^{st} input line ILc1 may be disposed on the first gate insulating layer 112. In an embodiment, the 3-1^{st} input line ILc1 may be disposed in the same layer as the gate electrode GE or the lower electrode CE1. The 3-1^{st} input line ILc1 may be formed together when the gate electrode GE is formed. The 3-1^{st} input line ILc1 may extend away from the intermediate area MCA. The 3-1^{st} input line ILc1 may be connected to the first input line ILa through contact holes penetrating the second gate insulating layer 113 and the inter-insulating layer 114. The 3-1^{st} input line ILc1 may be connected to a first connection pattern ILP1 through contact holes penetrating the second gate insulating layer 113 and the inter-insulating layer 114. The 3-1^{st} input line ILc1 may extend from a portion connected to the first input line ILa of the intermediate area MCA to the central corner area CCA (refer to FIG. 6), and may be disposed in the extending area SPA.

The 3-2^{nd} input line ILc2 may be disposed in the extending area SPA. The 3-2^{nd} input line ILc2 may be disposed in a layer of a level higher than that of the first input line ILa. The 3-2^{nd} input line ILc2 may be disposed in a layer of a level higher than that of the second input line ILb. The 3-2^{nd} input line ILc2 may be disposed on a second insulating layer 116h described below. The 3-2^{nd} input line ILc2 may be electrically connected to the 3-1^{st} input line ILc1 through the first connection pattern ILP1 and a second connection pattern ILP2. The 3-2^{nd} input line ILc2 may be connected to the second connection pattern ILP2 through a contact hole of the second insulating layer 116h. The first connection pattern ILP1 and the second connection pattern ILP2 may be connected to each other through a contact hole of the lower insulating layer 115. The 3-2^{nd} input line ILc2 may be electrically connected to the second input line ILb through a third connection pattern ILP3. The 3-2^{nd} input line ILc2 may be connected to the third connection pattern ILP3 through a contact hole of the second insulating layer 116h, and the third connection pattern ILP3 may be connected to the second input line ILb through a contact hole of the lower insulating layer 115.

Each of the first connection pattern ILP1 and the second connection pattern ILP2 may be disposed between the 3-1^{st} input line ILc1 and the 3-2^{nd} input line ILc2 in a cross-sectional view. The first connection pattern ILP1 may be disposed on the inter-insulating layer 114. The second connection pattern ILP2 and the third connection pattern ILP3 may be disposed on the lower insulating layer 115.

Each of the first input line ILa, the second input line ILb, and the third input line ILc may include a conductive material including molybdenum (Mo), aluminum (Al), copper (Cu), or titanium (Ti), and may have a single or multi-layer structure including the above material. Each of the first connection pattern ILP1, the second connection pattern ILP2, and the third connection pattern ILP3 may include a conductive material.

The first gate insulating layer 112, the second gate insulating layer 113, and the inter-insulating layer 114 may be also referred to as the inorganic insulating layer IIL. The buffer layer 111 and the inorganic insulating layer IIL may be disposed in the display area DA, the peripheral area PA, and the corner area CNA. The lower insulating layer 115 may be disposed on the inorganic insulating layer IIL. The lower insulating layer 115 may be disposed in the display area DA, the peripheral area PA, and the corner area CNA.

The lower insulating layer 115 may be disposed on the inter-insulating layer 114. The lower insulating layer 115 may cover the pixel circuit PC and the driving circuit DC. The lower insulating layer 115 may cover the drain electrode DE and the source electrode SE. In the central area CA, the lower insulating layer 115 may be disposed over the pixel circuit PC. In the extending area SPA, the lower insulating layer 115 may be disposed over the second driving circuit DC2. The first insulating layer 116 may be disposed on the lower insulating layer 115.

In the display area DA (e.g., the central area CA), a first connection electrode CML1 may be disposed on the lower insulating layer 115, and the first insulating layer 116 may be disposed on the lower insulating layer 115 while covering the first connection electrode CML1. The first connection electrode CML1 may be connected to the drain electrode DE or the source electrode SE through a contact hole of the lower insulating layer 115. A second connection electrode CML2 may be disposed on the first insulating layer 116, and the first upper insulating layer 117 may be disposed on the first insulating layer 116 while covering the second connection electrode CML2. The second connection electrode CML2 may be connected to the first connection electrode CML1 through a contact hole of the first insulating layer 116. Each of the first connection electrode CML1 and the second connection electrode CML2 may include a conductive material including molybdenum (Mo), aluminum (Al), copper (Cu), or titanium (Ti), and may have a single or multi-layer structure including the above material. In an embodiment, the first connection electrode CML1 may have a multi-layer structure including Ti/Al/Ti.

The display element DPE may be disposed on the first upper insulating layer 117. Although the display element DPE is disposed only on the first upper insulating layer 117 in FIG. 8A, the disclosure is not limited thereto, and the display element DPE may also be disposed on a second upper insulating layer 117h of the intermediate area MCA. The display element DPE may include a pixel electrode 211, an intermediate layer 212, and a counter electrode 213.

The pixel electrode 211 may be disposed on the first upper insulating layer 117. The pixel electrode 211 may be connected to the first thin-film transistor TFT1 through the first connection electrode CML1 and the second connection electrode CML2. The pixel electrode 211 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or any combinations thereof. In another embodiment, the pixel electrode 211 may further include a film including or consisting of ITO, IZO, ZnO, or In₂O₃ over/under the reflective film.

A pixel-defining layer 118 in which an opening 1180P exposing a portion of the pixel electrode 211 is defined may be disposed on the pixel electrode 211. The pixel-defining layer 118 may include an organic insulating material and/or an inorganic insulating material. The opening 1180P may define an emission area EA of light emitted by the display element. In an embodiment, a width of the opening 1180P may correspond to a width of the emission area EA, for example.

The intermediate layer 212 may be disposed on the pixel-defining layer 118. The intermediate layer 212 may include an emission layer disposed in the opening 1180P of the pixel-defining layer 118. The emission layer may include a high molecular weight organic material or a low molecular weight organic material emitting light of a predetermined color. Although not shown, a first functional layer and a second functional layer may be respectively disposed under and over the emission layer. The first functional layer may include, e.g., a hole transport layer (“HTL”), or may include a hole transport layer and a hole injection layer (“HIL”). The second functional layer may include an electron transport layer (“ETL”) and/or an electron injection layer (“EIL”). The first functional layer and the second functional layer may be common layers to cover the substrate 100 in the display area DA (refer to FIG. 6) and the intermediate area MCA, like the counter electrode 213.

The counter electrode 213 may include or consist of a conductive material having a low work function. In an embodiment, the counter electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloys thereof, for example. In an alternative embodiment, the counter electrode 213 may further include a layer including or consisting of ITO, IZO, ZnO, or In₂O₃ on the (semi)transparent layer including the above material.

In some embodiments, a capping layer (not shown) may be further disposed on the counter electrode 213. The capping layer may include an inorganic material (e.g., LiF), and/or an organic material.

In the corner area CNA (e.g., the intermediate area MCA and the extending area SPA), the second insulating layer 116h may be disposed on the lower insulating layer 115. In an embodiment, the second insulating layer 116h may be an insulating layer obtained when the first insulating layer 116 of the display area DA extends to the corner area CNA. The second insulating layer 116h may be formed in the same process as that of the first insulating layer 116, and a height of the second insulating layer 116h may be less than a height of the first insulating layer 116 by a subsequent process. In another embodiment, the second insulating layer 116h may be an insulating layer disposed on the lower insulating layer 115 through a separate process from that of the first insulating layer 116 of the display area DA. In the intermediate area MCA, the second upper insulating layer 117h may be disposed on the second insulating layer 116h. In an embodiment, the second upper insulating layer 117h may be an insulating layer obtained when the first upper insulating layer 117 of the display area DA extends to the corner area CNA. The second upper insulating layer 117h may be formed in the same process as that of the first upper insulating layer 117, and a height of the second upper insulating layer 117h may be less than a height of the first upper insulating layer 117 by a subsequent process. In another embodiment, the second upper insulating layer 117h may be an insulating layer disposed on the second insulating layer 116h through a separate process from that of the first upper insulating layer 117 of the display area DA.

Each of the lower insulating layer 115, the first insulating layer 116, the second insulating layer 116h, the first upper insulating layer 117, and the second upper insulating layer 117h may include an organic material. The lower insulating layer 115, the first insulating layer 116, the second insulating layer 116h, the first upper insulating layer 117, and the second upper insulating layer 117h may be also referred to as an organic insulating layer. In an embodiment, each of lower insulating layer 115, the first insulating layer 116, the second insulating layer 116h, the first upper insulating layer 117, and the second upper insulating layer 117h may include an organic insulating material such as a general-purpose polymer (e.g., PMMA or PS), a polymer derivative having a phenol-based group, an acrylic-based polymer, an imide-based polymer, an aryl ether-based polymer, an amide-based polymer, a fluorinated polymer, a p-xylene-based polymer, a vinyl alcohol-based polymer, or any combinations thereof, for example. In the intermediate area MCA, a third upper insulating layer 1181P may be disposed on the second upper insulating layer 117h. The third upper insulating layer 1181P may include an organic insulating material and/or an inorganic insulating material. In an embodiment, the third upper insulating layer 1181P may be formed in the same process as that of the pixel-defining layer 118, and a height of the third upper insulating layer 1181P may be less than a height of the pixel-defining layer 118 by a subsequent process.

The intermediate area MCA may include a first intermediate area in which the valley portion VP is disposed and a second intermediate area in which at least one dam is disposed. The first intermediate area may be between the central area CA and the second intermediate area. In the second intermediate area, the second voltage supply line 13 may be disposed.

In the first intermediate area, a first opening OP1 may be defined in the organic insulating layer. The first opening OP1 may be defined between the pixel circuit PC and the second voltage supply line 13. The first opening OP1 may be defined by removing parts of the lower insulating layer 115, the second insulating layer 116h, and the second upper insulating layer 117h. The first opening OP1 may be an opening where an opening of the lower insulating layer 115, an opening of the second insulating layer 116h, and an opening of the second upper insulating layer 117h overlap each other. An opening of the third upper insulating layer 1181P may overlap the first opening OP1. A top surface of the inter-insulating layer 114 may be exposed through the first opening OP1.

The first opening OP1 and the opening of the third upper insulating layer 1181P may be also referred to as the valley portion VP. A conductive pattern layer CPL may be disposed in the valley portion VP. The conductive pattern layer CPL may include a first conductive pattern layer CPL1 and a second conductive pattern layer CPL2 disposed on the first conductive pattern layer CPL1. The first conductive pattern layer CPL1 may contact the top surface of the inter-insulating layer 114, and may extend to a side wall of the first opening OP1 and a top surface of the second insulating layer 116h. Although a part of the first conductive pattern layer CPL1 may be disposed on a top surface of the lower insulating layer 115, the disclosure is not limited thereto. The second conductive pattern layer CPL2 may be disposed on the first conductive pattern layer CPL1, and may extend to a side wall of the first opening OP1 and a top surface of the second upper insulating layer 117h. Although a part of the second conductive pattern layer CPL2 may be disposed on the top surface of the lower insulating layer 115, the disclosure is not limited thereto.

The first dam DP1 and the second dam DP2 may be disposed in the second intermediate area. The first dam DP1 and the second dam DP2 may be disposed over the second voltage supply line 13. The first dam DP1 and the second dam DP2 may at least partially overlap the second voltage supply line 13. The first dam DP1 and the second dam DP2 may be disposed between the pixel circuit PC and the second driving circuit DC2.

In an embodiment, the first dam DP1 may be spaced apart from an organic encapsulation layer 320. At least a part of the first dam DP1 may not be covered by the organic encapsulation layer 320. Although the first dam DP1 may cover at least a part of the first input line ILa in an embodiment, the disclosure is not limited thereto.

The first dam DP1 may include a lower insulating pattern 115 Pa, a first insulating pattern 117 Pa, a first upper insulating pattern 118 Pa, and a second upper insulating pattern 119 Pa which are sequentially stacked. The lower insulating pattern 115 Pa may be disposed on the inter-insulating layer 114. The lower insulating pattern 115 Pa may be formed in the same process as that of the lower insulating layer 115, and the lower insulating pattern 115 Pa may include the same material as that of the lower insulating layer 115. The first insulating pattern 117 Pa may be formed in the same process as that of the first upper insulating layer 117 and/or the second upper insulating layer 117h, and the first insulating pattern 117 Pa may include the same material as that of the first upper insulating layer 117 and/or the second upper insulating layer 117h. The first upper insulating pattern 118 Pa may be formed in the same process as that of the third pixel-defining layer 118 and/or the third upper insulating layer 1181P, and the first upper insulating pattern 118 Pa may include the same material as that of the pixel-defining layer 118 and/or the third upper insulating layer 1181P. The second upper insulating pattern 119 Pa may be disposed on the first upper insulating pattern 118 Pa, may be formed in the same process as that of a spacer (not shown) disposed on the pixel-defining layer 118 in the display area, and may include the same material as that of the spacer.

The second dam DP2 may include a second insulating pattern 117Pb, a third upper insulating pattern 118Pb disposed on the second insulating pattern 117Pb, and a fourth upper insulating pattern 119Pb disposed on the third upper insulating pattern 118Pb. The second insulating pattern 117Pb may be formed in the same process as that of the first upper insulating layer 117 and/or the second upper insulating layer 117h, and the second insulating pattern 117Pb may include the same material as that of the first upper insulating layer 117 and/or the second upper insulating layer 117h. The third upper insulating pattern 118Pb may be formed in the same process as that of the third pixel-defining layer 118 and/or the third upper insulating layer 1181P, and the third upper insulating pattern 118Pb may include the same material as that of the pixel-defining layer 118 and/or the third upper insulating layer 1181P. The fourth upper insulating pattern 119Pb may be disposed on the third upper insulating pattern 118Pb, may be formed in the same process as that of the spacer (not shown) disposed on the pixel-defining layer 118 in the display area, and may include the same material as that of the spacer.

In the intermediate area MCA, a second opening OP2 corresponding to an area where the second voltage supply line 13 is disposed may be defined in the organic insulating layer. The second opening OP2 may be disposed between the first dam DP1 and the first opening OP1. The second opening OP2 may be disposed between the first dam DP1 and the valley portion VP. The second opening OP2 may be an opening where an opening passing through the lower insulating layer 115, an opening passing through the second insulating layer 116h, and an opening passing through the second upper insulating layer 117h overlap each other in the intermediate area MCA. An opening of the third upper insulating layer 1181P may overlap the second opening OP2. A top surface of the inter-insulating layer 114 may be exposed through the second opening OP2. The second insulating layer 116h in an area where the second opening OP2, the first dam DP1, and the second dam DP2 are disposed may be removed.

The second voltage supply line 13 may be disposed in the second opening OP2. The second voltage supply line 13 may be disposed over the inter-insulating layer 114 exposed through the second opening OP2. At least one conductive layer CL contacting the second voltage supply line 13 may be further disposed in the second opening OP2. The conductive layer CL may include one layer or a plurality of conductive layers, and the disclosure is not limited thereto. In an embodiment, the conductive layer CL may include a first conductive layer CL1 contacting the second voltage supply line 13, a second conductive layer CL2 on the first conductive layer CL1, and a third conductive layer CL3 on the second conductive layer CL2. The first conductive layer CL1 may be disposed along a side surface and a bottom surface of the opening passing through the lower insulating layer 115. A part of the first conductive layer CL1 may be disposed on the lower insulating layer 115 and the lower insulating pattern 115 Pa of the first dam DP1. The second conductive layer CL2 may be disposed over the first conductive layer CL1 along a side surface and a bottom surface of the opening passing through the lower insulating layer 115, and a part of the second conductive layer CL2 may be disposed on a side surface and a top surface of the second insulating layer 116h exposed through the second opening OP2 and the lower insulating pattern 115 Pa of the first dam DP1. The third conductive layer CL3 may be disposed along a side surface and a bottom surface of the opening of the second upper insulating layer 117h. A part of the third conductive layer CL3 may be disposed on the second upper insulating layer 117h and the first insulating pattern 117 Pa of the first dam DP1. Parts of the first conductive layer CL1 and the second conductive layer CL2 may be disposed in a part between the lower insulating pattern 115 Pa and the first insulating pattern 117 Pa of the first dam DP1. A part of the third conductive layer CL3 may be disposed in a part between the first insulating pattern 117 Pa and the first upper insulating pattern 118 Pa of the first dam DP1. The counter electrode 213 may be disposed on an uppermost layer from among the at least one conductive layer CL. In an embodiment, the counter electrode 213 may be disposed on the third conductive layer CL3, for example. The counter electrode 213 may extend from the display area DA to the peripheral area PA and the corner area CNA. The counter electrode 213 may extend to a part of the intermediate area MCA. In an embodiment, the counter electrode 213 may contact the third conductive layer CL3 and may be electrically connected to the second voltage supply line 13. Accordingly, in an embodiment, the counter electrode 213 may receive a power supply voltage.

A third opening OP3 may be further defined in the organic insulating layer between the extending area SPA and the intermediate area MCA. The third opening OP3 may be defined between the second driving circuit DC2 and the second voltage supply line 13. The third opening OP3 may be defined between the first dam DP1 and the second driving circuit DC2. Atop surface of the inter-insulating layer 114 may be exposed through the third opening OP3.

The thin-film encapsulation layer ENL may be disposed on the counter electrode 213. In an embodiment, the thin-film encapsulation layer ENL may include at least one inorganic encapsulation layer and at least one organic encapsulation layer. In an embodiment, the thin-film encapsulation layer ENL may include a first inorganic encapsulation layer 310, the organic encapsulation layer 320, and a second inorganic encapsulation layer 330 which are sequentially stacked, for example.

The organic encapsulation layer 320 may overlap at least a part of the second voltage supply line 13 in a direction perpendicular to the top surface of the substrate 100. The organic encapsulation layer 320 may be limited by the second dam DP2, and may not overlap the second driving circuit DC2 in a direction perpendicular to the top surface of the substrate 100. The organic encapsulation layer 320 may not be disposed in the extending area SPA. Because the organic encapsulation layer 320 is not disposed in the extending area SPA, stress applied in a process to the corner area CNA (refer to FIG. 3) may be reduced. In a cross-sectional view of the peripheral area PA (not shown), the organic encapsulation layer 320 may not overlap the first driving circuit DC1 of FIG. 3.

The first inorganic encapsulation layer 310 and the second inorganic encapsulation layer 330 may be entirely disposed in the central area CA and the intermediate area MCA. In a cross-sectional view of the peripheral area PA, the first inorganic encapsulation layer 310 and the second inorganic encapsulation layer 330 may be entirely disposed in the peripheral area PA. The first inorganic encapsulation layer 310 and the second inorganic encapsulation layer 330 may contact in at least a part of the intermediate area MCA and the extending area SPA. That is, the first inorganic encapsulation layer 310 and the second inorganic encapsulation layer 330 may contact in a part of the first corner area and the second corner area. In a cross-sectional view, the first inorganic encapsulation layer 310 and the second inorganic encapsulation layer 330 may be spaced apart from each other in a portion of the first corner area. In the third opening OP3, the first inorganic encapsulation layer 310 and the second inorganic encapsulation layer 330 may be disposed. In the third opening OP3, the first inorganic encapsulation layer 310 and the second inorganic encapsulation layer 330 may be sequentially stacked. In the third opening OP3, the first inorganic encapsulation layer 310 may be disposed on the inter-insulating layer 114.

The crack-preventing dam 120 may be disposed at an end of the corner area CNA (refer to FIG. 3). The crack-preventing dam 120 may be disposed at an end of the second corner area. As shown in FIG. 8A, the crack-preventing dam 120 may be disposed at an end of the extending area SPA. As shown in FIG. 8B, the crack-preventing dam 120 may be disposed at an end of the intermediate area MCA adjacent to the separation area SA.

In an area (not shown), the crack-preventing dam 120 may be disposed at an edge of the peripheral area PA (refer to FIG. 3). The crack-preventing dam 120 may extend along at least a part of an edge of the substrate 100 in the plan view of FIG. 3. In an embodiment, the crack-preventing dam 120 may have a shape that circles the display area DA (refer to FIG. 1) once, for example. In some sections, the crack-preventing dam 120 may have a discontinuous shape.

The crack-preventing dam 120 may have any of various shapes, and may be simultaneously including or consisting of the same material as some elements formed in the central area CA, or may have a multi-layer structure. In FIG. 8A, the crack-preventing dam 120 has a two-layer structure. The crack-preventing dam 120 may include a lower layer including the same material as that of the second gate insulating layer 113, and an upper layer including the same material as that of the inter-insulating layer 114 on the lower layer. The crack-preventing dam 120 may not be one, but a plurality of crack-preventing dams 120 may be provided to be spaced apart from each other. The crack-preventing dam 120 may be defined by removing parts of the second gate insulating layer 113 and the inter-insulating layer 114.

The crack-preventing dam 120 may be covered by a cover layer 130. The cover layer 130 may be a layer including or consisting of an organic material covering the crack-preventing dam 120 including an inorganic material. The cover layer 130 may cover the crack-preventing dam 120, and may fill an area where parts of the second gate insulating layer 113 and the inter-insulating layer 114 are removed.

Hereinafter, from among reference numerals in the description referring to the drawings, the same reference numerals as those in FIG. 8A denote the same or corresponding members, and thus a description thereof will be omitted for convenience.

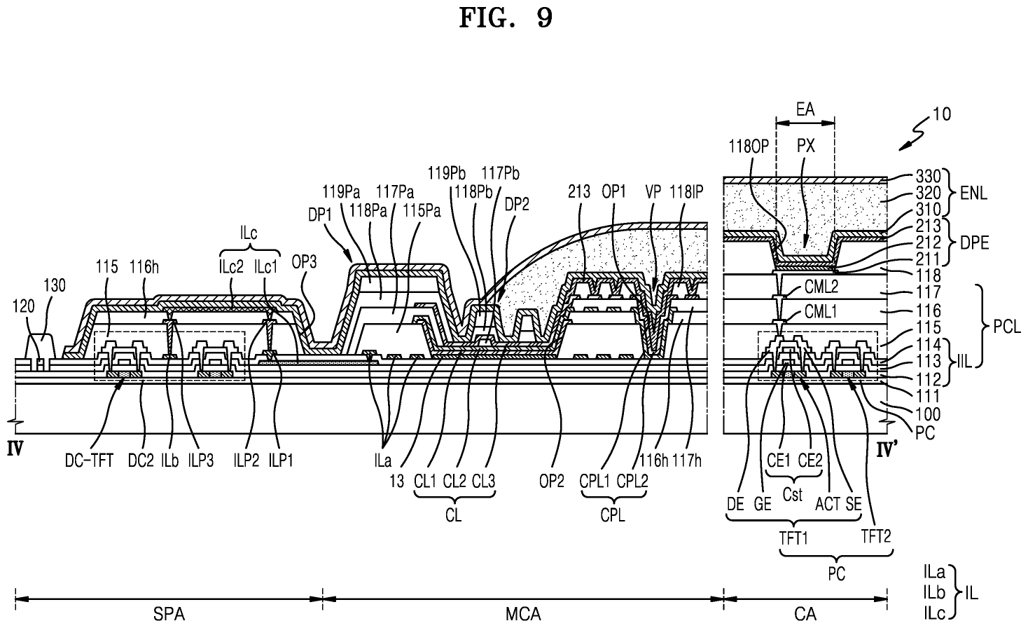

FIG. 9 is a cross-sectional view schematically illustrating another embodiment of a display panel, taken along line IV-IV′ of FIG. 6. FIG. 9 illustrates a modification of the third input line ILc.

Referring to FIG. 9, the 3-1^{st} input line ILc1 may be disposed on the second gate insulating layer 113. In an embodiment, the 3-1^{st} input line ILc1 may be disposed in the same layer as the upper electrode CE2. The 3-1^{st} input line ILc1 may be formed together when the upper electrode CE2 is formed. The 3-1^{st} input line ILc1 may be connected to the first input line ILa through a contact hole penetrating the inter-insulating layer 114. The 3-1^{st} input line ILc1 may be connected to the first connection pattern ILP1 through a contact hole penetrating the inter-insulating layer 114.

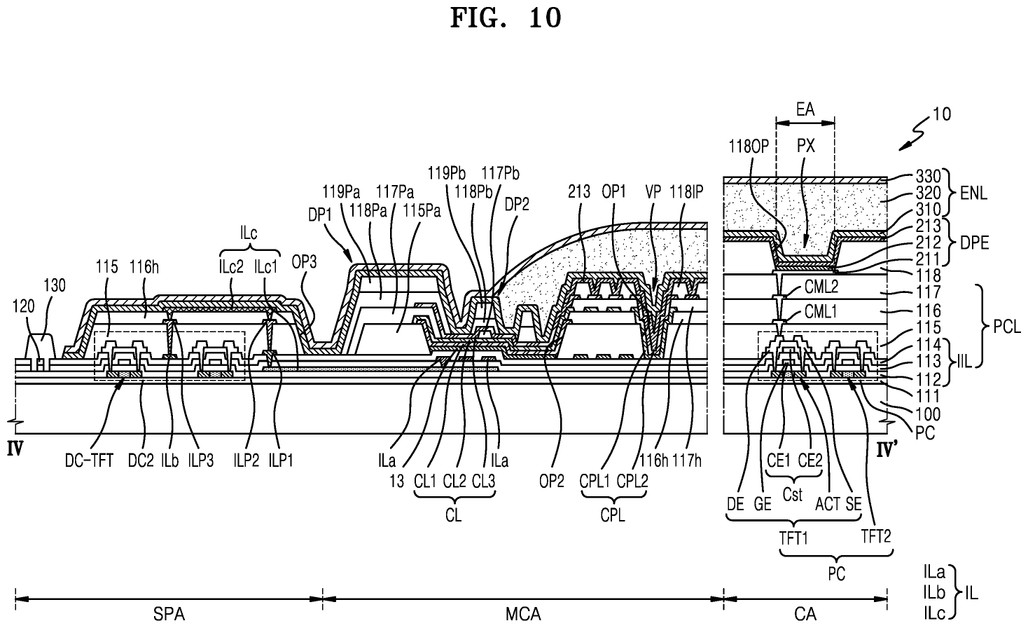

FIG. 10 is a cross-sectional view schematically illustrating another embodiment of a display panel, taken along line IV-IV′ of FIG. 6. FIG. 10 illustrates a modification of the input lines IL.

Referring to FIG. 10, the first input line ILa may overlap the second voltage supply line 13. The first input line ILa may be disposed in a different layer from the second voltage supply line 13. The first input line ILa may be disposed below the second voltage supply line 13. The first input line ILa may be disposed in a different layer from the second input line ILb. The first input line ILa may be disposed in the same layer as the upper electrode CE2. The first input line ILa may be disposed on the second gate insulating layer 113.

The 3-1^{st} input line ILc1 may be disposed under the first input line ILa, and may extend to the extending area SPA. The 3-1^{st} input line ILc1 may be disposed in the same layer as the lower electrode CE1. The 3-1^{st} input line ILc1 may be disposed on the first gate insulating layer 112. The first input line ILa may be connected to the 3-1^{st} input line ILc1 through a contact hole penetrating the second gate insulating layer 113.

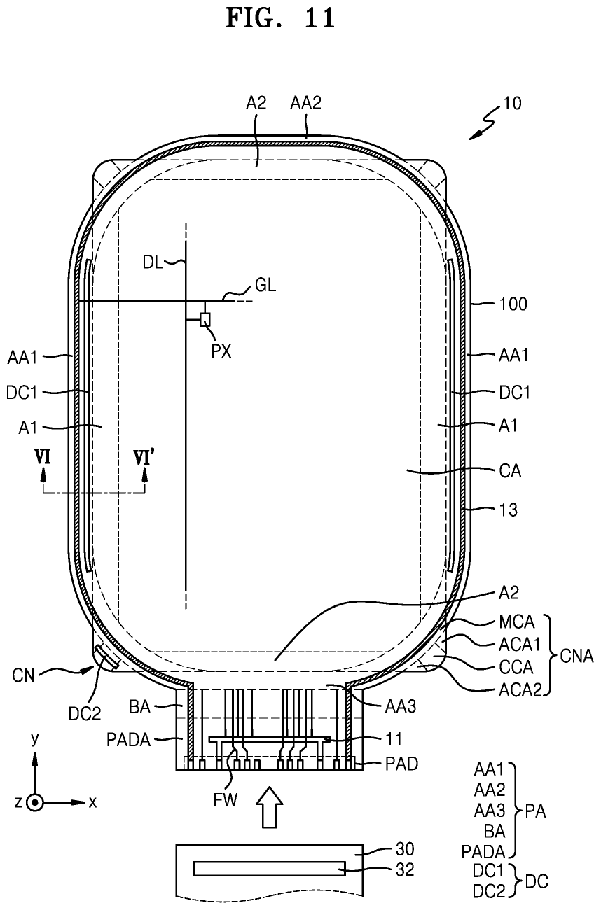

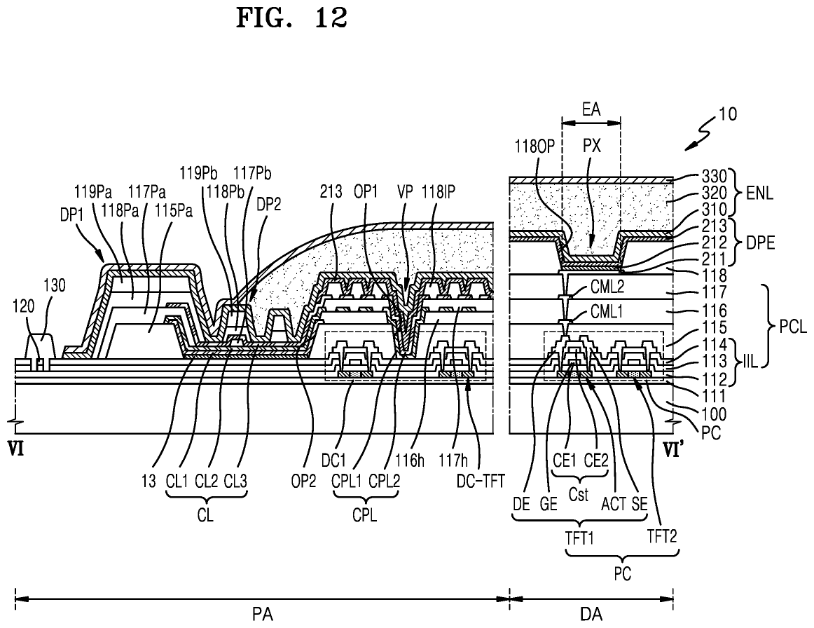

FIG. 11 is a plan view schematically illustrating another embodiment of a part of a display apparatus. FIG. 12 is a cross-sectional view schematically illustrating an embodiment of a display panel, taken along line VI-VI′ of FIG. 11. FIGS. 11 and 12 illustrate a modification of the first driving circuit DC1 and the second voltage supply line 13 in the peripheral area PA of the display panel 10.

Referring to FIG. 11, the second voltage supply line 13 may be disposed closer to an edge of the display panel 10 than the first driving circuit DC1 is to the edge of the display panel 10, and may be disposed closer to the central area CA of the display panel 10 than the second driving circuit DC2 is to the central area CA of the display panel 10. The first driving circuit DC1 may be disposed between the central area CA and the second voltage supply line 13, and the second driving circuit DC2 may be spaced apart from the central area CA with the second voltage supply line 13 therebetween.

Referring to FIG. 12, the display panel 10 may include the first driving circuit DC1, the valley portion VP, the first dam DP1, and the crack-preventing dam 120 in the peripheral area PA. The first driving circuit DC1 may be disposed between the second voltage supply line 13 and the central area CA. The first driving circuit DC1 may overlap at least a part of the organic encapsulation layer 320 in a direction perpendicular to a top surface of the substrate 100. The first driving circuit DC1 may include the driving circuit transistor DC-TFT. The valley portion VP may be disposed in an area overlapping the first driving circuit DC1. The valley portion VP may be disposed between the driving circuit transistors DC-TFT of the first driving circuit DC1. The first dam DP1 may be disposed between the first driving circuit DC1 and the crack-preventing dam 120. The second voltage supply line 13 may be disposed between the first dam DP1 and the first driving circuit DC1. The first dam DP1 may be disposed between the crack-preventing dam 120 and the second voltage supply line 13. The first dam DP1 may be disposed between the crack-preventing dam 120 and the first driving circuit DC1.

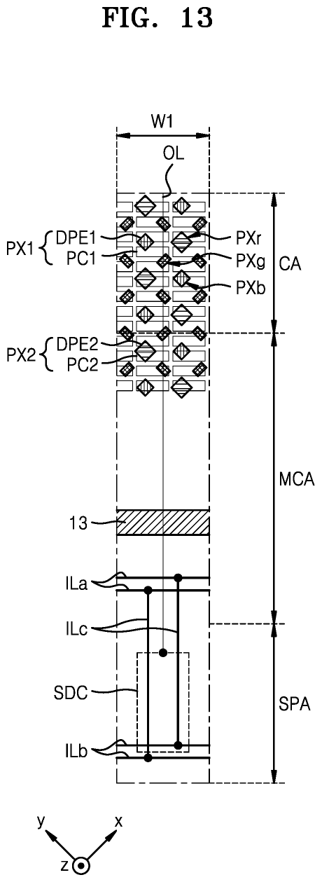

FIG. 13 is an enlarged view schematically illustrating an embodiment of a portion F of FIG. 6.

Referring to FIGS. 6 and 13 together, the display panel 10 may include one sub-driving circuit SDC in one extending area SPA.

The display panel 10 may include a substrate, the input line IL disposed on the substrate, first and second pixel circuits PC1 and PC2, a driving circuit including the sub-driving circuit SDC, the second voltage supply line 13, and first and second display elements DPE1 and DPE2. The first input line ILa, the second input line ILb, and the third input line ILc may each be a signal line for inputting/outputting/transmitting a signal.

A pixel arranged in the display area DA (refer to FIG. 6) including the central area CA is also referred to as a first pixel PX1, and a pixel arranged in the intermediate area MCA is also referred to as a second pixel PX2. Although the second pixel PX2 may be disposed in at least a portion of the intermediate area MCA in an embodiment, the disclosure is not limited thereto. In the central area CA and the intermediate area MCA, a plurality of plurality of pixels (e.g., PX1 and PX2) may be arranged in a pentile Matrix™ structure. However, the disclosure is not limited thereto, and an arrangement of the plurality of pixels may be changed in various ways.

In an embodiment, the plurality of pixels PX may include a red pixel PXr, a green pixel PXg, and a blue pixel PXb. In another embodiment, the plurality of pixels PX may include a red pixel, a green pixel, a blue pixel, and a white pixel. The first pixel PX1 may include the first pixel circuit PC1 and a first display element DPE1 connected to the first pixel circuit PC1. The second pixel PX2 may include the second pixel circuit PC2 and the second display element DPE2 connected to the second pixel circuit PC2. In an embodiment, the first and second display elements DPE1 and DPE2 may be organic light-emitting diodes, for example.

The sub-driving circuit SDC of the second driving circuit DC2 disposed in the extending area SPA may provide an electrical signal to the first pixel circuits PC1 of the first pixels PX1 arranged in the display area DA. The sub-driving circuit SDC of the second driving circuit DC2 disposed in the extending area SPA may provide an electrical signal to the second pixel circuits PC2 of the second pixels PX2 arranged in the intermediate area MCA.

The sub-driving circuit SDC disposed in the extending area SPA may be connected to the first input lines ILa through the second input lines ILb and the third input lines ILc. The sub-driving circuit SDC may be connected to an output line OL. Each sub-driving circuit SDC may receive a signal from the first input lines ILa, and may output a signal to the output line OL.

The output line OL may extend from an output terminal of the sub-driving circuit SDC to the display area DA, and may be connected to the pixels PX disposed in a direction from the output terminal of the sub-driving circuit SDC to the display area DA. The output line OL may be the gate line GL or the emission control line EL. The driving circuit DC may be spaced apart from the pixel circuit PC of the pixel PX and may be provided in the same layer. The sub-driving circuit SDC may be spaced apart from the pixel circuit PC of the pixel PX and may be provided in the same layer.

Hereinafter, from among reference numerals in the description referring to the drawings, the same reference numerals as those illustrated in FIG. 13 denote the same or corresponding members, and thus, a description thereof will be omitted for convenience.

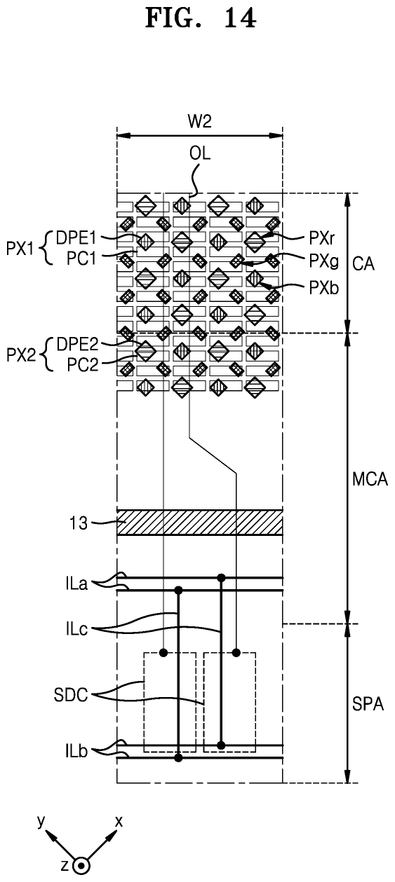

FIG. 14 is an enlarged view schematically illustrating another embodiment of the portion F of FIG. 6.

Referring to FIGS. 6 and 14 together, the display panel 10 may include a plurality of sub-driving circuits SDC in one extending area SPA. In the display panel 10, at least one sub-driving circuit SDC may be disposed in each of a plurality of extending areas SPA. In an embodiment, the number of sub-driving circuits SDC may vary according to a relative size of a width of one extending area SPA of the display panel 10. In an embodiment, because a second width W2 of the extending area SPA of FIG. 14 is greater than a first width W1 of the extending area SPA of FIG. 13, the number of sub-driving circuits SDC disposed in the extending area SPA of FIG. 14 may be relatively large, for example. In an embodiment, the number of sub-driving circuits SDC may vary according to a curvature of the corner area CNA of the display panel 10.

By embodiments, because a driving circuit is disposed closer to an outer edge of a display panel than a voltage supply line is to the outer edge of a display panel, a display area may be increased. By embodiments, because a driving circuit is included in an extending area disposed at an edge of a corner area, a display area for displaying an image may be increased. By embodiments, because an organic thin film layer of a thin-film encapsulation layer is not disposed in an extending area and only an inorganic thin film layer is disposed in the extending area, stress applied to a corner area may be reduced and thus reliability may be improved.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by one of ordinary skill in the art that various changes in form and details may be made therein without departing from the spirit and scope as defined by the following claims.

What is claimed is:

1. A display panel comprising:
a substrate comprising a central area and a corner area extending from a corner of the central area;
a pixel circuit disposed in the central area and a display element connected to the pixel circuit;
a voltage supply line which is disposed in the corner area and supplies a voltage to one electrode of the display element; and
a driving circuit which is disposed in the corner area and supplies an electrical signal to the pixel circuit,
wherein the driving circuit is spaced apart from the central area with the voltage supply line therebetween.

2. The display panel of claim 1, wherein the corner area comprises a first corner area adjacent to the central area and a second corner area outside the first corner area,
wherein the voltage supply line is disposed in the first corner area, and
the driving circuit is disposed in the second corner area.

3. The display panel of claim 2, further comprising a thin-film encapsulation layer disposed on the display element,
wherein the thin-film encapsulation layer comprises a first inorganic encapsulation layer, an organic encapsulation layer on the first inorganic encapsulation layer, and a second inorganic encapsulation layer on the organic encapsulation layer.

4. The display panel of claim 3, wherein the first inorganic encapsulation layer and the second inorganic encapsulation layer contact each other in the first corner area and the second corner area.

5. The display panel of claim 4, wherein the organic encapsulation layer overlaps at least a part of the voltage supply line and does not overlap the driving circuit.

6. The display panel of claim 4, wherein, in a cross-sectional view, the first inorganic encapsulation layer and the second inorganic encapsulation layer are spaced apart from each other in a portion of the first corner area.

7. The display panel of claim 4, further comprising a dam provided over the voltage supply line to at least partially overlap the voltage supply line, the dam being disposed between the pixel circuit and the driving circuit.

8. The display panel of claim 2, wherein
the second corner area comprises a plurality of extending areas, and
the driving circuit comprises a plurality of sub-driving circuits,
wherein at least one of the plurality of sub-driving circuits is disposed in each of the plurality of extending areas.

9. The display panel of claim 3, further comprising:
an organic insulating layer disposed on the substrate and covering the pixel circuit; and
an inorganic insulating layer disposed between the substrate and the organic insulating layer,
wherein a first opening between the pixel circuit and the voltage supply line in the first corner area and a second opening corresponding to the voltage supply line are defined in the organic insulating layer.

10. The display panel of claim 9, wherein the organic insulating layer is disposed over the driving circuit in the second corner area, and a third opening between the driving circuit and the voltage supply line is further defined in the organic insulating layer,
wherein the first inorganic encapsulation layer and the second inorganic encapsulation layer are disposed in the third opening.

11. The display panel of claim 9, further comprising:
at least one conductive layer disposed in the second opening of the organic insulating layer, and contacting the voltage supply line; and
an electrode disposed on an uppermost layer of the at least one conductive layer,
wherein the electrode is an extending portion of the one electrode of the display element.

12. The display panel of claim 2, further comprising:
a first input line disposed in the first corner area;
a second input line disposed in the second corner area and connected to the driving circuit; and
a third input line connecting the first input line to the second input line.

13. The display panel of claim 12, wherein each of the first input line, the second input line, and the third input line is spaced apart from the central area with the voltage supply line therebetween.

14. The display panel of claim 12, wherein the first input line is disposed in a same layer as the second input line and is disposed in a different layer from the third input line.

15. The display panel of claim 12, wherein the first input line overlaps the voltage supply line in a direction perpendicular to a top surface of the substrate.

16. The display panel of claim 1, further comprising a crack-preventing dam disposed at an end of the corner area.

17. A display panel comprising:
a substrate comprising a central area and a corner area extending from a corner of the central area, wherein the corner area comprises a first corner area adjacent to the central area and a second corner area outside the first corner area;
a pixel circuit disposed in the central area and a display element connected to the pixel circuit;
a voltage supply line which is disposed in the first corner area and supplies a voltage to one electrode of the pixel circuit;
a driving circuit which is disposed in the second corner area and supplies an electrical signal to the pixel circuit; and
an input line which is disposed outside the voltage supply line in the corner area and transmits a signal to the driving circuit.

18. The display panel of claim 17, further comprising a thin-film encapsulation layer comprising a first inorganic encapsulation layer disposed on the display element, an organic encapsulation layer on the first inorganic encapsulation layer, and a second inorganic encapsulation layer on the organic encapsulation layer,
wherein the organic encapsulation layer is disposed in the central area and the corner area, and does not overlap the driving circuit.

19. The display panel of claim 17, wherein the input line comprises a first input line disposed in the first corner area, a second input line disposed in the second corner area and connected to the driving circuit, and a third input line connecting the first input line to the second input line,
wherein the third input line comprises a 3-1^{st} input line disposed in a layer at a lower level than the first input line, and a 3-2^{nd} input line disposed in a layer at a higher level than the first input line.

20. The display panel of claim 17, wherein
the second corner area comprises a plurality of extending areas, and
the driving circuit comprises a plurality of sub-driving circuits,
wherein at least one of the plurality of sub-driving circuits is disposed in each of the plurality of extending areas.
